(19) United States
(12) Patent Application Publication
(10) Pub. No.: US 2012/0174975 A1
(43) Pub. Date: Jul. 12, 2012

(54) SOLAR CELL AND METHOD FOR MANUFACTURING THE SAME

(76) Inventors: Myungjun Shin, Seoul (KR); Sungjin Kim, Seoul (KR); Juhwa Cheong, Seoul (KR); Youngsung Yang, Seoul (KR); Taeyoung Kwon, Seoul (KR); Mann Yi, Seoul (KR); Gyeayoung Kwag, Seoul (KR); Seongeun Lee, Seoul (KR)

(21) Appl. No.: 13/346,251

(22) Filed: Jan. 9, 2012

(30) Foreign Application Priority Data
Jan. 10, 2011 (KR) 10-2011-0002374
Mar. 15, 2011 (KR) 10-2011-0022814
Mar. 28, 2011 (KR) 10-2011-0027687

(51) Int. Cl. H01L 31/0224

(52) U.S. Cl. 136/256

(57) ABSTRACT

A solar cell includes a substrate of a first conductive type, an emitter region of a second conductive type opposite the first conductive type which is positioned at the substrate and has a first sheet resistance, a first heavily doped region which is positioned at the substrate and has a second sheet resistance less than the first sheet resistance, a plurality of first electrodes which are positioned on the substrate, overlap at least a portion of the first heavily doped region, and are connected to the at least a portion of the first heavily doped region, and at least one second electrode which is positioned on the substrate and is connected to the substrate.

This application claims priority to and the benefit of Korean Patent Application No. 10-2011-0002374, 10-2011-0022814 and 10-2011-0027687, filed in the Korean Intellectual Property Office on Jan. 10, 2011, Mar. 15, 2011 and Mar. 28, 2011, respectively, the entire contents of which are incorporated herein by reference.

### BACKGROUND OF THE INVENTION

1. Field of the Invention

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts, which have different conductive types, for example, a p-type and an n-type, and form a p-n junction, and electrodes respectively connected to the semiconductor parts of the different conductive types.

When light is incident on the solar cell, electron-hole pairs are generated in the semiconductor parts. The electrons and the holes move under the influence of the p-n junction to the n-type semiconductor part and the p-type semiconductor part, respectively. The electrons and the holes are collected by the electrodes connected to the n-type semiconductor part and the p-type semiconductor part, respectively. The electrodes are connected to each other using electric wires to thereby obtain electric power.

### SUMMARY OF THE INVENTION

In one aspect, there is a solar cell including a substrate of a first conductive type, an emitter region of a second conductive type opposite the first conductive type positioned at the substrate, the emitter region having a first sheet resistance, a first heavily doped region positioned at the substrate, the first heavily doped region having a second sheet resistance less than the first sheet resistance, a plurality of first electrodes which are positioned on the substrate, overlap at least a portion of the first heavily doped region, and are connected to the at least a portion of the first heavily doped region, and at least one second electrode which is positioned on the substrate and is connected to the substrate, wherein the first heavily doped region has at least one of a structure including a first portion extending in a first direction and a second portion extending in a second direction different from the first direction and a structure extending in an oblique direction with respect to a side of the substrate.

The first portion and the second portion of the first heavily doped region may cross each other and may form a plurality of crossings. The first portion and the second portion may be connected to each other at the plurality of crossings.

Each of the plurality of first electrodes may extend along the plurality of crossings.

Each of the plurality of first electrodes may include a first portion extending in a third direction.

The third direction may be different from the first and second directions.

The third direction may be the same as one of the first and second directions.

The first heavily doped region may be positioned under the plurality of first electrodes and may further include a third portion extending in the third direction along the plurality of first electrodes.

Each of the plurality of first electrodes may further include a second portion extending in a fourth direction different from the third direction.

The first heavily doped region including the first and second portions may be disposed in a first lattice shape at the substrate, and the plurality of first electrodes including the first and second portions may be disposed in a second lattice shape on the substrate. The first lattice shape and the second lattice shape may be staggered at a predetermined angle or may be staggered by a predetermined distance in at least one of the third and fourth directions.

The solar cell may further include a first bus bar which is positioned on the substrate and is connected to the plurality of first electrodes.

The solar cell may further include a second heavily doped region having a third sheet resistance less than the second sheet resistance, the second heavily doped region being positioned under the plurality of first electrodes at the substrate and being connected to the plurality of first electrodes.

The first portion and the second portion of the first heavily doped region may not cross each other and may be not connected to each other.

The solar cell may further include a first bus bar which is positioned on the substrate and is connected to the plurality of first electrodes.

The first heavily doped region may further include a third portion extending in a third direction different from the first and second directions.

The third portion of the first heavily doped region may pass through a crossing of the first and second portions and may be connected to the first and second portions.

Each of the plurality of first electrodes may include a main branch, which is positioned on the third portion of the first heavily doped region and extends along the third portion, and at least one subsidiary branch, which is positioned on at least one of the first and second portions of the first heavily doped region and extends along the at least one of the first and second portions. The at least one subsidiary branch of one first electrode may be separated from another first electrode adjacent to the one first electrode.

Each of the plurality of first electrodes may include a main branch, which extends in a direction crossing the third portion of the first heavily doped region, and at least one subsidiary branch, which is positioned on at least one of the first and second portions of the first heavily doped region and extends along the at least one of the first and second portions.

Each of the plurality of first electrodes may include a main branch, which is positioned on one of the first and second portions of the first heavily doped region and extends along the one portion, and at least one subsidiary branch, which is positioned on the other of the first and second portions of the first heavily doped region and extends along the other portion. The at least one subsidiary branch of one first electrode may be separated from another first electrode adjacent to the one first electrode.

At least two of the first to third portions of the first heavily doped region may not cross each other and may be not connected to each other.

The substrate may have a plurality of via holes passing through the substrate. The plurality of first electrodes may be positioned on a first surface of the substrate, and the first bus bar may be positioned on a second surface opposite the first surface of the substrate. The plurality of first electrodes, the first bus bar, or both may be positioned inside the plurality of via holes, and the plurality of first electrodes and the first bus bar may be connected to each other through the plurality of via holes.

The plurality of via holes may be positioned at a location of the substrate corresponding to a crossing of the first and second portions of the first heavily doped region.

The substrate may have a plurality of via holes passing through the substrate. The plurality of first electrodes and the first bus bar may be positioned on a second surface opposite a first surface of the substrate on which light is incident. A portion of the first heavily doped region may be positioned inside the plurality of via holes and may be connected to the plurality of first electrodes.

The plurality of via holes may be positioned at a location of the substrate corresponding to a crossing of the first and second portions of the first heavily doped region.

The plurality of first electrodes may be positioned on a first surface of the substrate. The at least one second electrode may include a plurality of second electrodes positioned on a second surface opposite the first surface of the substrate. The first and second surfaces of the substrate may be incident surfaces, on which light is incident.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an embodiment of the invention;

FIG. 2 is a cross-sectional view taken along line II-II of FIG. 1;

FIG. 3 illustrates a disposition shape of a heavily doped region formed at a substrate in a solar cell according to an embodiment of the invention;

FIG. 4 is a partial plane view illustrating a disposition shape of a heavily doped region and a front electrode part including front bus bars in a solar cell according to an embodiment of the invention;

FIG. 5 is a partial plane view illustrating a disposition shape of a heavily doped region and a front electrode part in a solar cell according to an embodiment of the invention;

FIG. 6 is a partial plane view illustrating a disposition shape of a heavily doped region and a front electrode part not including a front bus bar in a solar cell according to an embodiment of the invention;

FIG. 7 is a cross-sectional view taken along line VII-VII of FIG. 6;

FIG. 8 is a partial plane view illustrating another disposition shape of a heavily doped region and a front electrode part including front bus bars in a solar cell according to an embodiment of the invention;

FIG. 9 is a cross-sectional view illustrating the connection of a plurality of solar cells using interconnectors according to an embodiment of the invention;

FIG. 10 is a partial plane view illustrating another disposition shape of a heavily doped region and a front electrode part not including a front bus bar in a solar cell according to an embodiment of the invention;

FIGS. 11 and 12 are partial plane views illustrating various disposition shapes of a heavily doped region and a front electrode part in a solar cell according to embodiments of the invention;

FIG. 13 is a partial perspective view of another example of a solar cell according to an embodiment of the invention;

FIG. 14 is a cross-sectional view taken along line XIV-XIV of FIG. 13;

FIG. 15 schematically illustrates a disposition shape of a heavily doped region, front electrodes, front bus bars, and via holes in a solar cell according to an embodiment of the invention;

FIG. 16 schematically illustrates another disposition shape of a heavily doped region, front electrodes, front bus bars, and via holes in a solar cell according to an embodiment of the invention;

FIG. 17 is a partial cross-sectional view of another example of a solar cell according to an embodiment of the invention;

FIG. 18 schematically illustrates a disposition shape of a heavily doped region, front electrodes, and front bus bars in a solar cell according to an embodiment of the invention;

FIG. 19 is a cross-sectional view taken along line XIX-XIX of FIG. 18;

FIG. 20 is another cross-sectional view taken along line XIX-XIX of FIG. 18;

FIGS. 21 and 22 schematically illustrate disposition shapes of a heavily doped region and front electrodes in a solar cell according to embodiments of the invention;

FIG. 23 is a partial perspective view of a solar cell according to another embodiment of the invention;

FIG. 24 is a cross-sectional view taken along line XXIII-XXIII of FIG. 23;

FIG. 25 is a schematic plane view of a solar cell shown in FIGS. 23 and 24;

FIGS. 26 to 29 are schematic plane views of various examples of a solar cell according to embodiments of the invention;

FIG. 30 is a partial perspective view of an example of a solar cell according to another embodiment of the invention;

FIG. 31 is a cross-sectional view taken along line XXXI-XXXI of FIG. 30;

FIG. 32 is a partial perspective view of another example of a solar cell according to another embodiment of the invention;

FIG. 33 is a cross-sectional view taken along line XXXIII-XXXIII of FIG. 32;

FIG. 34 is a schematic plane view of a portion of each of front and back surfaces of a substrate according to an embodiment of the invention, more specifically, (a) is a schematic plane view of a portion of the front surface of the substrate, and (b) is a schematic plane view of a portion of the back surface of the substrate; and

FIG. 35 is a schematic plane view of a back surface of a substrate of a solar cell shown in FIG. 32.

### DETAILED DESCRIPTION OF THE EMBODIMENTS

Embodiments of the invention will be described more fully hereinafter with reference to the accompanying drawings, in which example embodiments of the invention are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

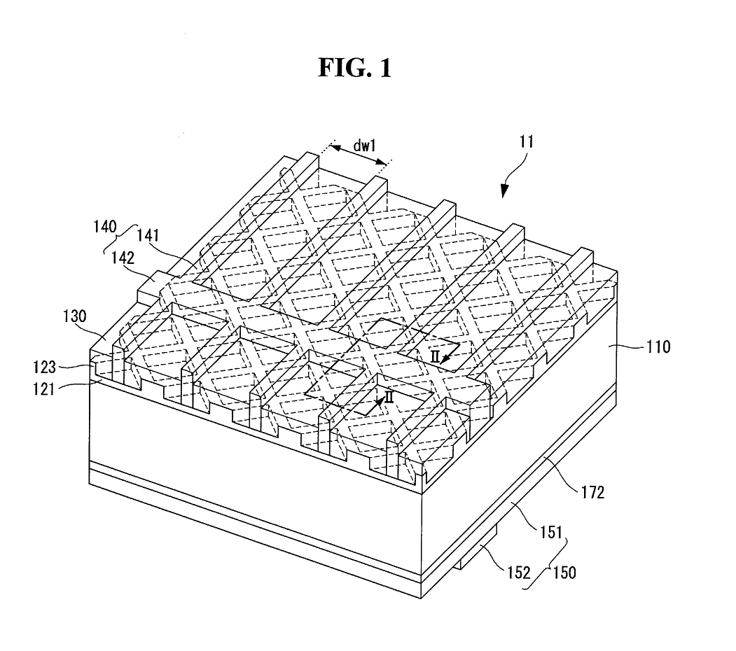

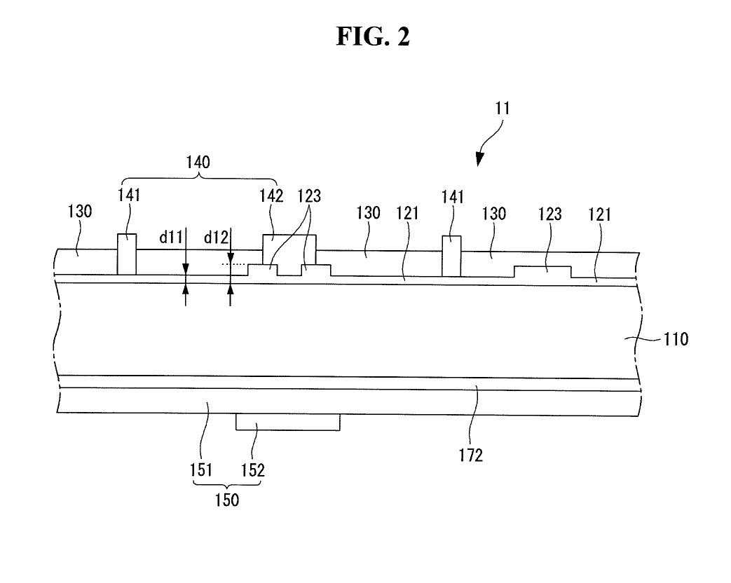

A solar cell according to an embodiment of the invention is described below with reference to FIGS. 1 and 2.

As shown in FIGS. 1 and 2, a solar cell 11 according to an embodiment of the invention includes a substrate 110, an emitter region 121 positioned at an incident surface (hereinafter, referred to as “a front surface or a first surface”) of the substrate 110 on which light is incident, a heavily doped region 123 which is positioned at the front surface of the substrate 110 and is connected to the emitter region 121, an anti-reflection layer 130 positioned on the emitter region 121 and the heavily doped region 123, a front electrode part (or a first electrode part) 140 which is connected to at least a portion of the emitter region 121 and at least a portion of the heavily doped region 123, a back surface field (BSF) region 172 which is positioned at a surface (hereinafter, referred to as “a back surface or a second surface”) opposite the front surface of the substrate 110, and a back electrode part (or a second electrode part) 150 positioned on the back surface of the substrate 110.

The substrate 110 is a semiconductor substrate formed of a semiconductor such as first conductive type silicon, for example, p-type silicon, though not required. The semiconductor is a crystalline semiconductor such as single crystal silicon and polycrystalline silicon.

When the substrate 110 is of the p-type, the substrate 110 is doped with impurities of a group III element such as boron (B), gallium (Ga), and indium (In). Alternatively, the substrate 110 may be of an n-type. When the substrate 110 is of the n-type, the substrate 110 may be doped with impurities of a group V element such as phosphorus (P), arsenic (As), and antimony (Sb).

Unlike the configuration shown in FIGS. 1 and 2, in an alternative example, the front surface of the substrate 110 may have a textured surface corresponding to an uneven surface having a plurality of protrusions and a plurality of depressions or having uneven characteristics. In this instance, each of the emitter region 121, the heavily doped region 123, and the anti-reflection layer 130 positioned on the front surface of the substrate 110 may have the textured surface. The textured surface may be formed through a separate process performed on a flat surface of the substrate 110. For example, the textured surface may be formed through a saw damage removing process for removing a saw damage portion, which is generated in a slicing process for manufacturing a solar cell substrate from a silicon ingot, using HF, etc., or a texturing process through the dry or wet etching after completing the saw damage removing process.

As described above, if the front surface of the substrate 110 has the textured surface through the separate process, an incidence area of the substrate 110 may increase and a light reflectance may decrease due to a plurality of reflection operations resulting from the textured surface. Hence, an amount of light incident on the substrate 110 may increase, and the efficiency of the solar cell 11 may be improved.

The emitter region 121 is an impurity doped region formed by doping the substrate 110 with impurities of a second conductive type (for example, n-type) opposite the first conductive type (for example, p-type) of the substrate 110. The emitter region 121 is positioned at the front surface of the substrate 110. Thus, the emitter region 121 of the second conductive type forms a p-n junction along with a first conductive type region of the substrate 110.

Electrons and holes produced by light incident on the substrate 110 move to corresponding components by a built-in potential difference resulting from the p-n junction between the substrate 110 and the emitter region 121. Namely, the electrons move to the n-type semiconductor, and the holes move to the p-type semiconductor. Thus, when the substrate 110 is of the p-type and the emitter region 121 is of the n-type, the holes move to the back surface of the substrate 110 and the electrons move to the emitter region 121.

Because the emitter region 121 forms the p-n junction along with the first conductive type region of the substrate 110, the emitter region 121 may be of the p-type when the substrate 110 is of the n-type unlike the embodiment of the invention. In this instance, the electrons move to the back surface of the substrate 110 and the holes move to the emitter region 121.

Returning to the embodiment of the invention, when the emitter region 121 is of the n-type, the emitter region 121 may be formed by doping the substrate 110 with impurities of a group V element. On the contrary, when the emitter region 121 is of the p-type, the emitter region 121 may be formed by doping the substrate 110 with impurities of a group III element.

The heavily doped region 123 is an impurity doped region which is more heavily doped than the emitter region 121 with impurities of the same conductive type as the emitter region 121. Thus, the emitter region 121 and the heavily doped region 123 are the impurity doped regions doped with impurities of the second conductive type.

Impurity doping concentrations of the emitter region 121 and the heavily doped region 123 are different from each other. More specifically, the impurity doping concentration of the heavily doped region 123 is higher than the impurity doping concentration of the emitter region 121. The heavily doped region 123 forms a p-n junction along with the substrate 110 in the same manner as the emitter region 121. Hence, when the substrate 110 is of the p-type and the heavily doped region 123 is of the n-type, the holes move to the back surface of the substrate 110 and the electrons move to the heavily doped region 123 as well as the emitter region 121 due to the p-n junction between the substrate 110 and the heavily doped region 123 in the same manner as the emitter region 121. Further, an impurity doping thickness d11 of the emitter region 121 is different from an impurity doping thickness d12 of the heavily doped region 123. For example, the impurity doping thickness d11 of the emitter region 121 is less than the impurity doping thickness d12 of the heavily doped region 123.

As described above, because the impurity doping thickness d11 of the emitter region 121 is different from the impurity doping thickness d12 of the heavily doped region 123, an upper surface of the heavily doped region 123 (i.e., a surface contacting the anti-reflection layer 130) of the heavily doped region 123 protrudes beyond an upper surface (i.e., a surface contacting the anti-reflection layer 130) of the emitter region 121 towards the anti-reflection layer 130. Hence, the upper surface of the emitter region 121 and the upper surface of the heavily doped region 123 are positioned on different lines parallel to the back surface of the substrate 110. Thus, the front surface of the substrate 110, on which the emitter region 121 and the heavily doped region 123 are formed, has an uneven surface because of a difference between the impurity doping thicknesses d11 and d12 of the emitter region 121 and the heavily doped region 123. In this instance, if the front surface of the substrate 110 has the textured surface, it may be considered that the impurity doping thicknesses d11 and d12 of the emitter region 121 and the heavily doped region 123 are substantially equal to each other within the margin of error obtained by a difference between heights of the protrusions of the textured front surface.

Sheet resistances of the emitter region 121 and the heavily doped region 123 are different from each other because of the difference between the impurity doping thicknesses d11 and d12 of the emitter region 121 and the heavily doped region 123. In general, the sheet resistance is inversely proportional to an impurity doping thickness. Therefore, in the embodiment of the invention, because the impurity doping thickness d11 of the emitter region 121 is less than the impurity doping thickness d12 of the heavily doped region 123, the sheet resistance of the emitter region 121 is greater than the sheet resistance of the heavily doped region 123. For example, the sheet resistance of the emitter region 121 may be approximately 80 Ω/sq. to 150 Ω/sq., and the sheet resistance of the heavily doped region 123 may be approximately 5 Ω/sq. to 30 Ω/sq.

As shown in FIGS. 1, 3, and 4, the heavily doped region 123 having the relatively high impurity doping concentration extends in a first direction, and a second direction crossing the first direction at the substrate 110.

Accordingly, the heavily doped region 123 is disposed in a lattice shape (for example, a first lattice shape) at the front surface of the substrate 110. The first direction and the second direction are not a direction parallel to the side of the substrate 110 but an oblique direction inclined to the side of the substrate 110. Therefore, the heavily doped region 123 is not disposed in the direction parallel to the side of the substrate 110 and extends while making predetermined angles θ1 and θ2 with the side of the substrate 110.

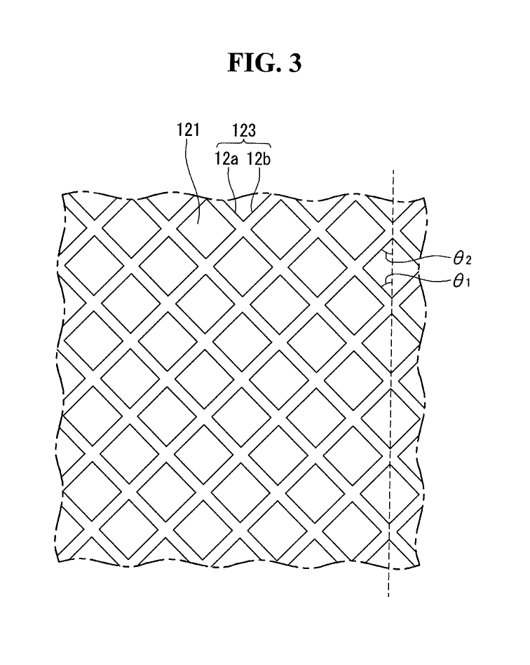

The angle θ1 is an angle between a first portion 12a of the heavily doped region 123 extending in the first direction and the side of the substrate 110. The angle θ2 is an angle between a second portion 12b of the heavily doped region 123 extending in the second direction and the side of the substrate 110. The angles θ1 and θ2 are greater than 0° and less than 90°. For example, the angles θ1 and θ2 shown in FIG. 3 are about 45°. In FIG. 3, the first direction and the second direction cross each other at a right angle. However, the first direction and the second direction may cross each other at a predetermined angle, which is greater than 0° and less than 90°.

Because a portion excluding the heavily doped region 123 from the impurity doped region of the front surface of the substrate 110 is the emitter region 121, the emitter region 121 surrounded by the heavily doped region 123 has a diamond shape as shown in FIG. 3.

As described above, when the electrons and the holes move under the influence of the p-n junction between the first conductive type region of the substrate 110 and the emitter region 121, a loss amount of carriers resulting from a moving direction of carriers and impurities may vary due to the emitter region 121 and the heavily doped region 123, which have the different sheet resistances and the different impurity doping concentrations.

In other words, the movement of carriers when carriers move through a relatively low sheet resistance portion of an impurity doped region doped with impurities of a second conductive type is generally easier than the movement of carriers when the carriers move through a relatively high sheet resistance portion of the impurity doped region doped with the impurities of the second conductive type. Further, as an impurity doping concentration of the impurity doped region increases, the conductivity of the impurity doped region increases.

Accordingly, as in the embodiment of the invention, when the corresponding carriers (for example, electrons) move to the emitter region 121 and the heavily doped region 123, carriers positioned in the emitter region 121 having the relatively high sheet resistance move to the heavily doped region 123, which has the relatively low sheet resistance less than the emitter region 121 and is positioned close to the emitter region 121. In this instance, because the impurity doping concentration of the emitter region 121 is less than the impurity doping concentration of the heavily doped region 123, a loss amount of carriers resulting from the impurities when the carriers move from the emitter region 121 to the heavily doped region 123 is greatly reduced, compared to when the carriers move through the heavily doped region 123.

As described above, when the carriers positioned in the emitter region 121 move to the heavily doped region 123 having the relatively low sheet resistance, the carriers moving to the heavily doped region 123 move along the heavily doped region 123 extending in the first and second directions because the conductivity of the heavily doped region 123 is greater than the conductivity of the emitter region 121. Thus, the heavily doped region 123 serves as a semiconductor electrode or a semiconductor channel for transferring carriers.

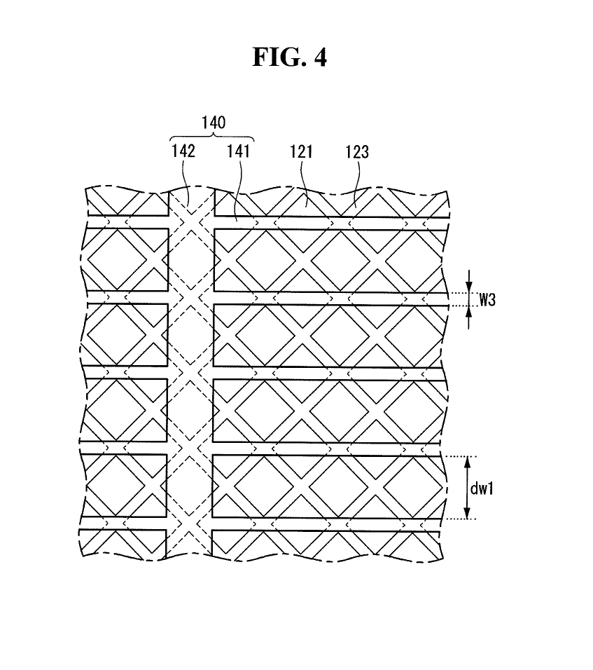

In this instance, as shown in FIG. 4, a portion of the emitter region 121 and a portion of the heavily doped region 123 adjoin the front electrode part 140, and the front electrode part 140 contains a metal. Therefore, the conductivity of the front electrode part 140 is much greater than the conductivity of the heavily doped region 123 as well as the conductivity of the emitter region 121. Thus, carriers moving along the heavily doped region 123 extending in the first and second directions move to the front electrode part 140, and carriers positioned in the emitter region 121 adjoining the front electrode part 140 or carriers adjacent to the front electrode part 140 move to the front electrode part 140.

As described above, the carriers move to not only the emitter region 121 adjoining the front electrode part 140 but also to the heavily doped region 123 adjacent to the emitter region 121 because of the formation of the heavily doped region 123. Hence, various moving directions of carriers may be obtained, and a moving distance of carriers may decrease.

As described above, the heavily doped region 123 is disposed in the lattice shape at the substrate 110, and the lattice shape of the heavily doped region 123 extends in a direction different from the disposition direction of the front electrode part 140. Hence, the moving distance of carriers to the heavily doped region 123 or the front electrode part 140 may further decrease. Further, the moving direction of carriers to the heavily doped region 123 or the front electrode part 140 may be further differ or be diverse.

Thus, an amount of carriers lost during the movement of carriers from the impurity doped regions 121 and 123 to the front electrode part 140 decreases. As a result, an amount of carriers transferred to the front electrode part 140 increases.

When the sheet resistance of the emitter region 121 is equal to or less than about 150 Ω/sq., a shunt error, in which the front electrode part 140 positioned on the emitter region 121 passes through the emitter region 121 and contacts the substrate 110, is prevented. When the sheet resistance of the emitter region 121 is equal to or greater than about 80 Ω/sq., an amount of light absorbed in the emitter region 121 further decreases, and an amount of light incident on the substrate 110 increases. Further, a loss of carriers resulting from impurities further decreases.

When the sheet resistance of the heavily doped region 123 is equal to or less than about 30 Ω/sq., the conductivity of the heavily doped region 123 is stably secured. Hence, a moving amount of carrier may further increase. When the sheet resistance of the heavily doped region 123 is equal to or greater than about 5 Ω/sq., an amount of light absorbed in the heavily doped region 123 further decreases and an amount of light incident on the substrate 110 increases.

The anti-reflection layer 130 positioned on the emitter region 121 and the heavily doped region 123 reduces a reflectance of light incident on the solar cell 11 and increases selectivity of a predetermined wavelength band, thereby increasing the efficiency of the solar cell 11.

The anti-reflection layer 130 may be formed of a material capable of transmitting light, for example, hydrogenated silicon nitride (SiNx), hydrogenated silicon oxide (SiOx), hydrogenated silicon nitride-oxide (SiNxOy), etc. Further, the anti-reflection layer 130 may be formed of a transparent material. The anti-reflection layer 130 may have a thickness of about 70 nm to 80 nm and a refractive index of about 2.0 to 2.1.

When the refractive index of the anti-reflection layer 130 is equal to or greater than about 2.0, the reflectance of light decreases and an amount of light absorbed in the anti-reflection layer 130 further decreases. Further, when the refractive index of the anti-reflection layer 130 is equal to or less than about 2.1, the reflectance of light further decreases.

Further, in the embodiment of the invention, the anti-reflection layer 130 has a refractive index of about 2.0 to 2.1 between a refractive index (about 1) of air and a refractive index (about 3.5) of the substrate 110. Thus, because a refractive index in going from air to the substrate 110 gradually increases, the reflectance of light further decreases by the gradual increase in the refractive index. As a result, an amount of light incident on the substrate 110 further increases.

When the thickness of the anti-reflection layer 130 is equal to or greater than about 70 nm, an anti-reflection effect of light is more efficiently obtained. When the thickness of the anti-reflection layer 130 is equal to or less than about 80 nm, an amount of light absorbed in the anti-reflection layer 130 decreases and an amount of light incident on the substrate 110 increases. Further, in the process for manufacturing the solar cell 11, the front electrode part 140 stably and easily passes through the anti-reflection layer 130 and is stably connected to the emitter region 121.

The anti-reflection layer 130 performs a passivation function that converts a defect, for example, dangling bonds existing at and around the surface of the substrate 110 into stable bonds using hydrogen (H) contained in the anti-reflection layer 130 to thereby prevent or reduce a recombination and/or a disappearance of carriers moving to the surface of the substrate 110. Hence, the anti-reflection layer 130 reduces an amount of carriers lost by the defect at the surface of the substrate 110.

The anti-reflection layer 130 shown in FIGS. 1 and 2 has a single-layered structure, but may have a multi-layered structure, for example, a double-layered structure. The anti-reflection layer 130 may be formed of at least one of silicon nitride (SiNx), silicon oxide (SiOx), silicon nitride-oxide (SiNxOy), aluminum oxide (AlxOy), and titanium oxide (TiOx). The anti-reflection layer 130 may be omitted, if necessary or desired.

As described above, in the embodiment of the invention, the impurity doped regions of the second conductive type include the emitter region 121 and the heavily doped region 123 which are different from each other in the sheet resistance, the impurity doping thickness, and the impurity doping concentration.

The impurity doped regions may be formed by forming an impurity doped region doped with impurities of the second conductive type using a thermal diffusion method or an ion implantation method, and then forming the emitter region 121 and the heavily doped region 123 using an etchback method for partially removing the impurity doped region or a laser doping method for selectively applying a laser beam onto the impurity doped region. For example, when the etchback method is used, an etched portion of the impurity doped region is the emitter region 121, and a non-etched portion of the impurity doped region is the heavily doped region 123. Further, when the laser doping method is used, a portion of the impurity doped region, onto which the laser beam is applied, is the heavily doped region 123, and a portion of the impurity doped region, onto which the laser beam is not applied, is the emitter region 121.

The emitter region 121 and the heavily doped region 123 shown in FIGS. 1 and 2 are formed using the thermal diffusion method and the etchback method as an example.

For example, n-type or p-type impurities such as phosphorus (P) and boron (B) may be diffused into the substrate 110 to form the impurity doped region. Then, a portion of the impurity doped region may be etched and removed to form the emitter region 121 and the heavily doped region 123 which are different from each other in the sheet resistance, the impurity doping thickness, and the impurity doping concentration.

In this instance, because the impurity doping concentration increases as impurities go from the p-n junction surface to the front surface of the substrate 110, a concentration of inactive impurities increases as the inactive impurities go from the p-n junction surface to the front surface of the substrate 110. Thus, the inactive impurities are gathered at and around the front surface of the substrate 110 and form a dead region at and around the front surface of the substrate 110. A loss of carriers is generated by the inactive impurities existing in the dead region. In the embodiment of the invention, impurities, which are diffused into the substrate 110 and are not normally combined with (i.e., are insoluble in) materials, for example, silicon of the substrate 110, are referred to as inactive impurities.

In the embodiment of the invention, because the emitter region 121 and the heavily doped region 123 are formed using the etching method, the heavily doped region is removed by etching the front surface of the substrate 110 by a desired amount. Further, at least a portion of the dead region existing at the front surface of the substrate 110 is removed through the removal of the heavily doped region in the etching process. As described above, as the dead region is removed, the recombination of carriers resulting from impurities existing at the dead region is greatly reduced and a loss amount of carriers is greatly reduced. Further, because the anti-reflection layer 130 is positioned on the emitter region 121, whose defect is greatly removed through the removal of at least a portion of the dead region, the passivation effect of the anti-reflection layer 130 is further improved.

Alternatively, if the emitter region 121 and the heavily doped region 123 are formed using methods other than the etching method and the thermal diffusion method, a location of the p-n junction surface between the emitter region 121 and the substrate 110 and a location of the p-n junction surface between the heavily doped region 123 and the substrate 110 may be different from each other unlike the structure illustrated in FIGS. 1 and 2. Instead, the front surface of the substrate 110, on which the emitter region 121 and the heavily doped region 123 are formed, may be a flat surface.

The front electrode part 140 includes a plurality of front electrodes (or a plurality of first electrodes) 141 and a plurality of front bus bars (or a plurality of first bus bars) 142 connected to the plurality of front electrodes 141.

The plurality of front electrodes 141 are positioned on a portion of the emitter region 121 and a portion of the heavily doped region 123, and are electrically and physically connected to the portion of the emitter region 121 and the portion of the heavily doped region 123.

As shown in FIGS. 1 to 4, the plurality of front electrodes 141 are spaced apart from one another at a distance therebetween and extend parallel to one another in a fixed direction. The plurality of front electrodes 141 extend in a third direction different from the extension direction (i.e., the first and second directions) of the heavily doped region 123. The third direction is a direction parallel to the upper and lower sides of the substrate 110 in FIG. 3. Thus, the front electrodes 141 may be parallel to one side of the substrate 110, and each front electrode 141 may be positioned on different straight lines of each of the first and second portions 12a and 12b of the heavily doped region 123.

Hence, each front electrode 141 is connected to the portion of the emitter region 121 as well as the portion of the heavily doped region 123. As shown in FIG. 4, each front electrode 141 extends in a straight line along crossings of the first and second portions 12a and 12b of the heavily doped region 123 extending in the first and second directions, and thus, is connected to the heavily doped region 123 at the crossings.

As described above, because the front electrodes 141 are directly connected to the portion of the emitter region 121 and the portion of the heavily doped region 123, the anti-reflection layer 130 does not exist under the front electrodes 141.

The front electrodes 141 are formed of at least one conductive material, for example, silver (Ag).

The front electrodes 141 collect carriers (for example, electrons) moving through the portion of the emitter region 121 and the portion of the heavily doped region 123. Because each front electrode 141 is connected to the heavily doped region 123 at the crossings of the first and second portions 12a and 12b, each front electrode 141 collects carriers moving along the heavily doped region 123 more than the emitter region 121.

Because the heavily doped region (corresponding to the semiconductor electrode) 123 is formed in a non-formation portion of the front electrodes 141 in a direction crossing the front electrodes 141, a moving distance of carriers moving to the front electrodes 141 or the heavily doped region 123 decrease. Thus, when carriers move to the front electrodes 141 or the heavily doped region 123, an amount of carriers lost by the impurities or the defect decreases by a reduction in the moving distance of carriers.

Only the anti-reflection layer 130, which does not adversely affect the light transmission by the substrate 110, is positioned on the emitter region 121 and the heavily doped region 123, on which the front electrodes 141 are not formed.

Thus, a reduction in the incidence area of light resulting from the heavily doped region 123 does not occur. On the other hand, as described above, an amount of carriers moving to the front electrodes 141 greatly increases without reducing the incidence area of light because of the reduction in the movement distance of carriers and the reduction in the loss amount of carriers.

An amount of carriers moving to the front electrodes 141 increases due to the presence of the heavily doped region 123, and a design tolerance of the front electrodes 141 increases. In other words, because an amount of carriers collected by the heavily doped region 123 for assisting the front electrodes 141 increases, the efficiency of the solar cell 11 is not reduced by a reduction in a collection amount of carriers resulting from an increase in a distance between the front electrodes 141 positioned on the emitter region 121.

In the embodiment of the invention, a distance dw1 between the two adjacent front electrodes 141 may be greater than a distance between two adjacent front electrodes in a comparative example of a solar cell not including the heavily doped region 123 by about 0.5 mm to 1.5 mm. For example, while the distance between the two adjacent front electrodes in the comparative example is about 2.5 mm, the distance dw1 between the two adjacent front electrodes 141 in the embodiment of the invention may be about 3.0 mm to 4.0 mm.

As described above, as the distance dw1 between the two adjacent front electrodes 141 increases, the number of front electrodes 141 positioned on the front surface of the substrate 110 corresponding to the incident surface decreases. Hence, the incidence area of the front surface of the substrate 110 increases. Further, because the formation area of the front electrodes 141 containing an expensive material, for example, silver (Ag) decreases, the manufacturing cost of the solar cell 11 is reduced.

The plurality of front bus bars 142 are electrically and physically connected to the emitter region 121 and the heavily doped region 123, are spaced apart from one another in a direction crossing the front electrodes 141, and extend substantially parallel to one another.

The extension direction of the front bus bars 142 is different from the first and second directions of the heavily doped region 123 and the third direction of the front electrodes 141. The extension direction of the front bus bars 142 is a fourth direction crossing (for example, perpendicular to) the third direction. Thus, the fourth direction is the direction parallel to the left and right sides of the substrate 110 in FIG. 4.

Hence, each front electrode 141 forms an angle of 90° with the left and right sides of the substrate 110 in FIG. 4. Further, in FIG. 4, each front bus bar 142 forms an angle of 90° with the upper and lower sides of the substrate 110.

The plurality of front bus bars 142 are electrically and physically connected to the front electrodes 141 at crossings of the front electrodes 141 and the front bus bars 142.

Accordingly, as shown in FIGS. 1 to 4, the plurality of front electrodes 141 have a stripe shape extending in a transverse (or longitudinal) direction, and the plurality of front bus bars 142 have a stripe shape extending in a longitudinal (or transverse) direction. Hence, the front electrode part 140 has a lattice shape on the front surface of the substrate 110.

As shown in FIG. 4, each front bus bar 142 extends in a straight line along the crossings of the first and second portions 12a and 12b of the heavily doped region 123 extending in the first and second directions in the same manner as the front electrodes 141. The crossings of the first and second portions 12a and 12b are positioned in a middle portion of each front bus bar 142. Hence, an amount of carriers moving from the front electrodes 141 to the front bus bars 142 increases.

As described above, because the angles θ1 and θ2 between the heavily doped region 123 and the side of the substrate 110 are different from the angle between the front electrode 141 and the side of the substrate 110, the front electrode 141 and the first portion 12a of the heavily doped region 123 and/or the front electrode 141 and the second portion 12b of the heavily doped region 123 are staggered at a predetermined angle (for example, 45°) as shown in FIG. 4, although both the heavily doped region 123 and the front electrode part 140 have the lattice shape at the front surface of the substrate 110.

The plurality of front bus bars 142 collect not only carriers moving from a portion of the emitter region 121 and a portion of the heavily doped region 123, but also carriers, which are collected by the front electrodes 141. In this instance, because the crossings of the first and second portions 12a and 12b of the heavily doped region 123 are positioned in a middle portion of each front bus bar 142, an amount of carriers moving from the front electrodes 141 to the front bus bars 142 increases.

The plurality of front bus bars 142 are connected to an external device through a conductive tape such as an interconnector containing a conductive material and output collected carriers (for example, electrons) to the external device.

Because each front bus bar 142 has to collect carriers collected by the front electrodes 141 crossing the front bus bar 142 and has to transfer the collected carriers in a desired direction, a width of each front bus bar 142 is greater than the width of each front electrode 141.

Because carriers move through the heavily doped region 123 and the emitter region 121 as well as the front electrodes 141 and are collected by the front bus bars 142, a carrier collection amount of the solar cell 11 greatly increases.

In the embodiment of the invention, because the anti-reflection layer 130 is formed of silicon nitride (SiNx) having the characteristic of positive fixed charges, the transfer efficiency of carriers from the substrate 110 to the front electrode part 140 when the substrate 110 is of the p-type is improved. In other words, because the anti-reflection layer 130 has the positive charge characteristic, the anti-reflection layer 130 reduces or prevents a movement of holes corresponding to positive charges.

More specifically, when the substrate 110 is of the p-type and the anti-reflection layer 130 has the positive charge characteristic, electrons corresponding to negative charges moving to the anti-reflection layer 130 have the polarity opposite the anti-reflection layer 130. Therefore, the electrons are drawn to the anti-reflection layer 130 due to the polarity of the anti-reflection layer 130, and the holes having the same polarity as the anti-reflection layer 130 are pushed out of the anti-reflection layer 130 due to the polarity of the anti-reflection layer 130.

Accordingly, an amount of electrons moving from the substrate 110 to the front electrode part 140 increases due to silicon nitride (SiNx) having the positive polarity, and the movement of undesired carriers (for example, holes) is more efficiently reduced or prevented. As a result, an amount of carriers recombined at the front surface of the substrate 110 further decreases.

In the embodiment of the invention, the front bus bars 142 are formed of the same material as the front electrodes 141.

In the embodiment of the invention, the number of front electrodes 141 and the number of front bus bars 142 may vary, if necessary or desired.

The BSF region 172 is a region (for example, a p⁺-type region) that is more heavily doped than the substrate 110 with impurities of the same conductive type as the substrate 110.

A potential barrier is formed by a difference between impurity concentrations of a first conductive region (for example, a p-type region) of the substrate 110 and the BSF region 172. Hence, the potential barrier prevents or reduces electrons from moving to the BSF region 172 used as a moving path of holes, and makes it easier for the holes to move to the BSF region 172. Thus, the BSF region 172 reduces an amount of carriers lost by a recombination and/or a disappearance of the electrons and the holes at and around the back surface of the substrate 110, and accelerates a movement of desired carriers (for example, holes), thereby increasing the movement of carriers to the back electrode part 150.

The back electrode part 150 includes a back electrode (or a second electrode) 151 and a plurality of back bus bars (or a plurality of second bus bars) 152 connected to the back electrode 151.

The back electrode 151 contacts the BSF region 172 positioned at the back surface of the substrate 110 and is substantially positioned on the entire back surface of the substrate 110. In an alternative example, the back electrode 151 may be not positioned at an edge of the back surface of the substrate 110.

The back electrode 151 contains a conductive material, for example, aluminum (Al).

The back electrode 151 collects carriers (for example, holes) moving to the BSF region 172.

Because the back electrode 151 contacts the BSF region 172 having the impurity concentration higher than the substrate 110, a contact resistance between the substrate 110 (i.e., the BSF region 172) and the back electrode 151 decreases. Hence, the transfer efficiency of carriers from the substrate 110 to the back electrode 151 is improved.

The plurality of back bus bars 152 are positioned on the back electrode 151 to be opposite to the plurality of front bus bars 142 with the substrate 110 interposed therebetween. However, in an alternative example, the back bus bars 152 may be positioned directly on the back surface of the substrate 110 and may adjoin the back electrode 151. In this instance, the back electrode 151 may be positioned on the remaining back surface of the substrate 110 excluding the formation area of the back bus bars 152, or on the remaining back surface of the substrate 110 excluding the formation area of the back bus bars 152 and the edges. Further, the back electrode 151 may partially overlap the back bus bars 152.

The plurality of back bus bars 152 collect carriers transferred from the back electrode 151 in the same manner as the plurality of front bus bars 142.

The plurality of back bus bars 152 are connected to the external device through the conductive tape and output carriers (for example, holes) collected by the back bus bars 152 to the external device.

The plurality of back bus bars 152 may be formed of a material having better conductivity than the back electrode 151. The plurality of back bus bars 152 may contain at least one conductive material, for example, silver (Ag).

An operation of the solar cell 11 having the above-described structure is described below.

When light irradiated to the solar cell 11 is incident on the emitter region 121, the heavily doped region 123, and the substrate 110, which are the semiconductor parts, through the anti-reflection layer 130, a plurality of electron-hole pairs are generated in the semiconductor parts 121, 123, and 110 by light energy produced based on the incident light. In this instance, because a reflection loss of the light incident on the substrate 110 is reduced by the anti-reflection layer 130, an amount of light incident on the substrate 110 increases.

The electron-hole pairs are separated into electrons and holes by the p-n junction of the substrate 110 and the impurity doped regions 121 and 123. Then, the separated electrons move to the n-type semiconductor part, for example, the emitter region 121 and the heavily doped region 123, and the separated holes move to the p-type semiconductor part, for example, the substrate 110. The electrons moving to the emitter region 121 and the heavily doped region 123 are collected by the front electrodes 141 and the front bus bars 142, and then move along the front bus bars 142. The holes moving to the substrate 110 are collected by the back electrode 151 and the back bus bars 152, and then move along the back bus bars 152. When the front bus bars 142 are connected to the back bus bars 152 using electric wires, current flows therein to thereby enable use of the current for electric power.

Further, because the heavily doped region 123 (i.e., the semiconductor electrode) having the relatively high impurity doping concentration is formed in the direction crossing the front electrodes 141, carriers moving from the emitter region 121 to the front electrodes 141 or the front bus bars 142 move to the front electrodes 141 or the front bus bars 142 through not only the front electrodes 141 or the front bus bars 142 but also the heavily doped region 123. Thus, the movement distance of carriers moving from the emitter region 121 to the front electrodes 141, the front bus bars 142, or the heavily doped region 123 decreases, and the various moving directions of carriers are obtained. Further, an amount of carriers moving to the front electrode part 140 or the heavily doped region 123 increases. As a result, an amount of carriers output from the solar cell 11 increases.

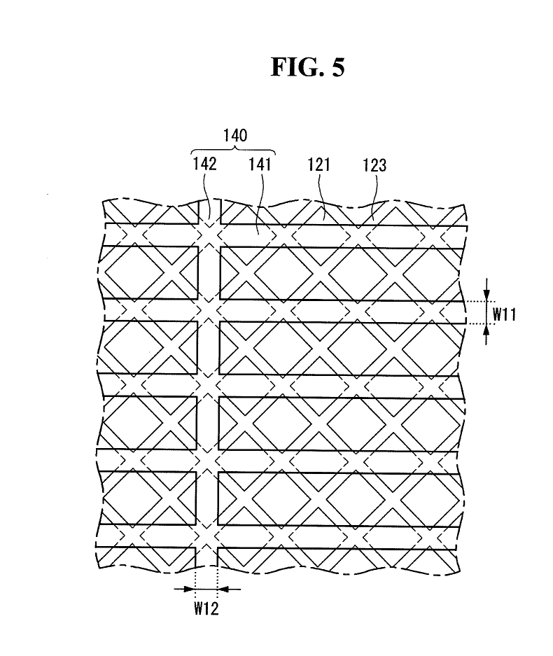

Hereinafter, another example of the solar cell according to the embodiment of the invention is described with reference to FIG. 5.

As shown in FIG. 5, the solar cell includes a plurality of front electrodes 141 extending in the third direction and a plurality of front bus bars 142, which extend in the fourth direction and are connected to the plurality of front electrodes 141, in the same manner as the configuration of FIG. 4. Further, unlike the configuration of FIG. 4, a width W11 of each of the front electrodes 141 is substantially equal to a width W12 of each of the front bus bars 142.

In other words, because an amount of carriers moving to an external device increases due to a heavily doped region 123, an amount of carriers output to the external device increases although the width W12 of the front bus bar 142 is not greater than the width W11 of the front electrode 141.

Accordingly, although the width W12 of the front bus bar 142 is substantially equal to the width W11 of the front electrode 141, the amount of carriers output to the external device does not decrease. Therefore, the width W11 of each front electrode 141 and the width W12 of each front bus bar 142 may be substantially equal to each other and may be about 80 μm to 120 μm, for example.

When the front bus bar 142 having the size of about 1.5 mm to 2 mm, for example, has the same width (for example, about 80 μm to 120 μm) as the front electrode 141, a formation area of the front bus bars 142 is greatly reduced. Hence, an incidence area of light incident on the substrate 110 increases, and the efficiency of the solar cell is further improved. Further, the manufacturing cost of the front bus bars 142 is reduced.

In an alternative example, the widths W11 and W12 of the front electrode 141 and the front bus bar 142 may be less than the width W3 of the front electrode 141 shown in FIG. 4 and may be less than about 80 μm to 120 μm, for example.

As described above, because an amount of carriers output to the external device increases due to the presence of the heavily doped region 123, an amount of carriers output to the external device when the width of the front electrode part 140 (that is, the width of each front electrode 141 and the width of each front bus bar 142) decreases does not greatly decrease, as compared an amount of carriers output to the external device when the heavily doped region 123 is not included. In this instance, because the formation area of the front electrode part 140 disturbing (or interfering with) the incidence of light on the substrate 110 decreases, the incidence area of light on the substrate 110 increases. Hence, the efficiency of the solar cell is further improved, and the manufacturing cost of the front bus bars 142 is reduced.

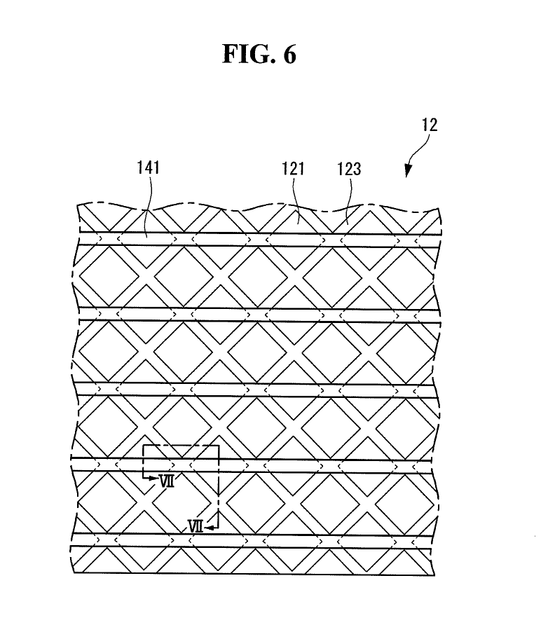

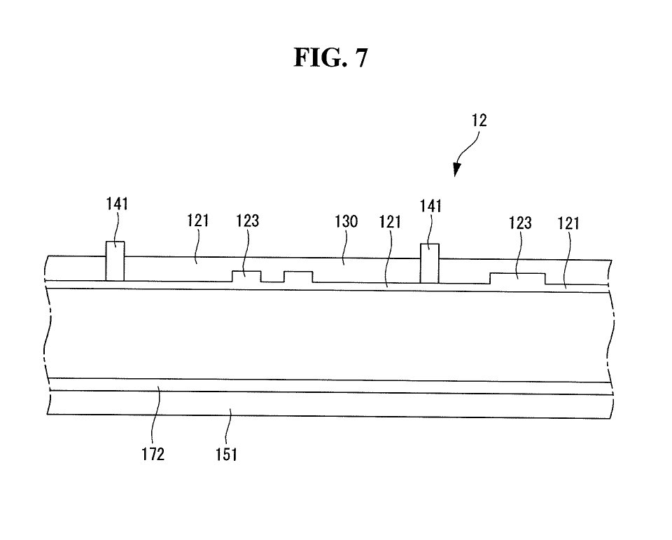

In another example of the solar cell according to the embodiment of the invention, as shown in FIGS. 6 and 7, a solar cell 12 does not include the front bus bar on the front surface of the substrate 110, at which the emitter region 121 and the heavily doped region 123 each having the lattice shape are formed, and also does not include the back bus bar on the back surface of the substrate 110. Hence, only a plurality of front electrodes 141 are formed on the front surface of the substrate 110 to extend parallel to one another in a fixed direction, and only a back electrode 151 is formed on the back surface of the substrate 110. As described above, the back electrode 151 may be not formed at an edge of the back surface of the substrate 110.

Since configuration of the solar cell 12 shown in FIGS. 6 and 7 is substantially the same as the solar cell 11 shown in FIGS. 1 and 2 except the omission of the front bus bar and the back bus bar, a further description may be briefly made or may be entirely omitted.

Carriers (for example, electrons) collected by the front electrodes 141 move along a conductive adhesive part attached to a corresponding location in a direction crossing the front electrodes 141 and then are output to the external device. Further, carriers (for example, holes) moving to the back electrode 151 move along a conductive adhesive part attached to a corresponding location on the back electrode 151 and then are output to the external device. In an alternative example, an interconnector may be additionally attached to the conductive adhesive part.

The conductive adhesive part may be formed of a material different from the front electrodes 141 and the back electrode 151.

The conductive adhesive part may be formed of a conductive adhesive film, a conductive paste, a conductive epoxy, etc.

The conductive adhesive film may include a resin and conductive particles distributed into the resin. A material of the resin is not particularly limited as long as it has the adhesive property. It is preferable, but not required, that a thermosetting resin is used for the resin so as to increase the adhesive reliability.

The thermosetting resin may use at least one selected among epoxy resin, phenoxy resin, acryl resin, polyimide resin, and polycarbonate resin.

The resin may further contain a predetermined material, for example, a known curing agent and a known curing accelerator other than the thermosetting resin.

For example, the resin may contain a reforming material such as a silane-based coupling agent, a titanate-based coupling agent, and an aluminate-based coupling agent, so as to improve an adhesive strength between a conductive pattern part and the solar cell 12. The resin may contain a dispersing agent such as calcium phosphate and calcium carbonate, so as to improve the dispersibility of the conductive particles. The resin may contain a rubber component such as acrylic rubber, silicon rubber, and urethane rubber, so as to control the modulus of elasticity of the conductive adhesive film.

A material of the conductive particles is not particularly limited as long as it has the conductivity. The conductive particles may contain at least one metal selected among copper (Cu), silver (Ag), gold (Au), iron (Fe), nickel (Ni), lead (Pb), zinc (Zn), cobalt (Co), titanium (Ti), and magnesium (Mg) as the main component. The conductive particles may be formed of only metal particles or metal-coated resin particles. The conductive adhesive film having the above-described configuration may further include a peeling film.

It is preferable, but not required, that the conductive particles use the metal-coated resin particles, so as to mitigate a compressive stress of the conductive particles and improve the connection reliability of the conductive particles.

It is preferable, but not required, that the conductive particles have a diameter of about 2 μm to 30 μm, so as to improve the dispersibility of the conductive particles.

It is preferable, but not required, that a composition amount of the conductive particles distributed into the resin is about 0.5% to 20% based on the total volume of the conductive adhesive film in consideration of the connection reliability after the resin is cured. When the composition amount of the conductive particles is less than about 0.5%, a current may not smoothly flow because a physical contact area between the conductive adhesive part and the front electrodes decreases. When the composition amount of the conductive particles is greater than about 20%, the adhesive strength may be reduced because a composition amount of the resin relatively decreases.

When the interconnector is additionally formed, the resin may be positioned between the conductive particles and the front and back electrodes 141 and 151, and between the conductive particles and the interconnector in a state where the front and back electrodes 141 and 151 are attached to the interconnector using the conductive adhesive film. Alternatively, the conductive particles may directly contact the front and back electrodes 141 and 151, the interconnector, or both.

Accordingly, carriers moving to the front and back electrodes 141 and 151 jump to the conductive particles and then jump to the interconnector. In other words, the carriers moving to the front and back electrodes 141 and 151 may move to the interconnector through the conductive particles or may directly move to the interconnector.

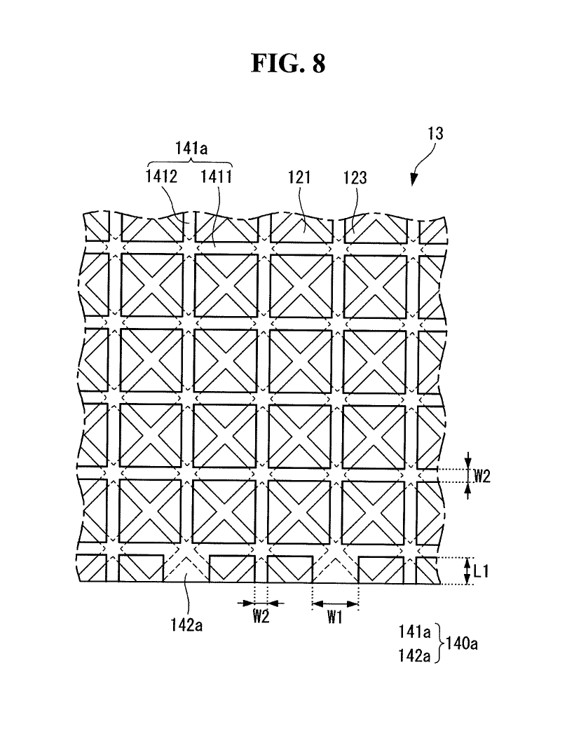

Hereinafter, a solar cell 13 according to another embodiment of the invention is described with reference to FIG. 8.

As shown in FIG. 8, the solar cell 13 includes a front electrode part 140a including a front electrode 141a and a plurality of front bus bars 142a which are positioned on a front surface of a substrate 110 at which an impurity doped region including a heavily doped region 123 having a lattice shape is formed.

Configuration of a back surface of the substrate 110 in the solar cell 13 is substantially the same as FIGS. 1 and 2. Namely, the solar cell 13 includes a back electrode 151 positioned on the back surface of the substrate 110, a plurality of back bus bars 152 connected to the back electrode 151, and a BSF region 172 positioned at the back surface of the substrate 110 on which the back electrode 151 is positioned. Each of the plurality of back bus bars 152 elongates (or extends) in a fixed direction. Further, the plurality of back bus bars 152 extend on the back surface of the substrate 110 at a location opposite to the plurality of front bus bars 142a. The back bus bars 152 and the front bus bars 142a may be aligned.

The front electrode 141a includes a plurality of first portions 1411, which extend parallel to one another in the third direction and are spaced apart from one another, and a plurality of second portions 1412, which extend parallel to one another in the fourth direction and are spaced apart from one another. Namely, the second portions 1412 extend in the fourth direction, i.e., the extension direction of the front bus bars 142 of FIG. 4. Hence, as shown in FIG. 8, the front electrode 141a is disposed on an emitter region 121 in a lattice shape (for example, a second lattice shape), similar to the disposition shape of the front electrodes 141 and the front bus bars 142 of the solar cells 11 and 12. Because the lattice shape of the front electrode 141a and the lattice shape of the heavily doped region 123 are staggered at a predetermined angle (for example, 45°), first and second portions 12a and 12b of the heavily doped region 123 are positioned on straight lines different from the first and second portions 1411 and 1412 of the front electrode 141a.

As described above, because the front electrode 141a extends in both transverse and longitudinal directions, the formation area of the front electrode 141a increases. Hence, an amount of carriers collected by the front electrode 141a greatly increases.

In the solar cell 13 shown in FIG. 8, each of the plurality of front bus bars 142a extends from the front electrode 141 (for example, the first portion 1411 of the front electrode 141a) closest to one surface (the back surface in FIG. 7) of the substrate 110 to the surface of the substrate 110, and is connected to the front electrode 141a closest to the one surface. The front bus bars 142a are spaced apart from one another at a predetermined distance. A width W1 of each front bus bar 142a is greater than a width W2 of each of the first and second portions 1411 and 1412 of the front electrode 141a. Each front bus bar 142a extends to an edge of the substrate 110. Thus, a length L1 of the front bus bar 142a is much shorter than a length of the front bus bar 142 of FIGS. 1 and 2. Hence, the length of each front bus bar 142a is shorter than a length of each back bus bar 152.

As described above, a reduction in the formation area of the front bus bars 142a compensates for a reduction in the incidence area of light resulting from an increase in the formation area of the front electrodes 141a, and thus, a reduction in an amount of light incident on the substrate 110 is reduced or prevented.

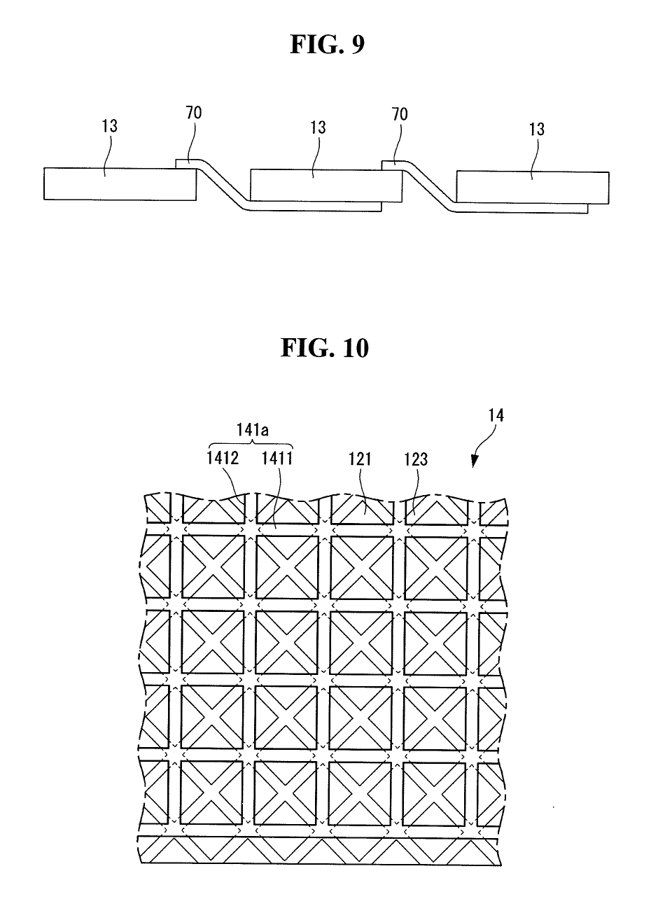

In this instance, the conductive tape, i.e., an interconnector 70 shown in FIG. 9 is positioned between the front bus bars 142a of one of the two adjacent solar cells 13 and the back bus bars 152 of the other solar cell, thereby electrically connecting the two adjacent solar cells 13 in series or in parallel to each other. Hence, carriers collected by the solar cells 13 are transferred to the external device. In the embodiment of the invention, because the length L1 of the front bus bar 142a is shorter than the length of the back bus bar 152 as shown in FIG. 8, a length of a portion of the interconnector 70 positioned on the front bus bars 142a is shorter than a length of a portion of the interconnector 70 positioned on the back bus bars 152. Hence, an amount of the interconnector 70 used decrease, and the manufacturing cost of the solar cell 13 is reduced.

When the front electrodes 141a positioned on the front surface of the substrate 110 have the lattice shape as shown in FIG. 8, a solar cell 14 according to the embodiment of the invention shown in FIG. 10 includes only front electrodes 141a having the lattice shape and does not include the front bus bar. In this instance, as described above with reference to FIGS. 6 and 7, the solar cell 14 does not include the back bus bar on the back surface of the substrate 110.

Accordingly, the structure of a front electrode part on the front surface of the substrate 110 in the solar cell 14 including a heavily doped region 123 is substantially the same as the structure obtained by removing the front bus bars 142a from the structure shown in FIG. 8. Further, the structure of the back surface of the substrate 110 in the solar cell 14 is substantially the same as the structure shown in FIGS. 6 and 7.

As described above with reference to FIGS. 6 and 7, carriers collected by the front electrodes 141a are output to the external device by attaching the conductive adhesive part to the front and back electrodes 141a and 151 on the front and back surfaces of the substrate 110.

In this instance, because the front and back bus bars requiring the expensive manufacturing cost are omitted due to the heavily doped region 123 and the front electrodes 141a of the lattice shape, the manufacturing cost of the solar cell 14 is reduced.

Because the front electrodes 141a shown in FIGS. 8 and 10 have the formation area greater than the front electrodes 141 shown in FIGS. 1, 2 and 4, the front electrodes 141a have a line resistance less than the front electrodes 141. Further, an amount of carriers moving through the first and second portions 1411 and 1412 of the front electrodes 141a is less than an amount of carriers moving through the front electrodes 141.

Accordingly, in an alternative example, because a carrier transfer burden on each of the first and second portions 1411 and 1412 of the front electrode 141a is less than a carrier transfer burden on the front electrode 141, the widths W1 and W2 of the first and second portions 1411 and 1412 of the front electrode 141a may be less than the width W3 of the front electrode 141 shown in FIGS. 1, 2 and 4. For example, the width W3 of the front electrode 141 shown in FIGS. 1, 2 and 4 may be about 80 μm to 120 μm, and the widths W1 and W2 of the first and second portions 1411 and 1412 of the front electrode 141a shown in FIGS. 8 and 10 may be about 40 μm to 100 μm.

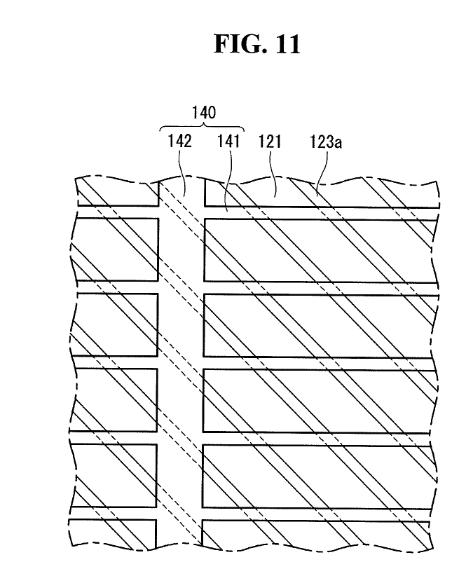

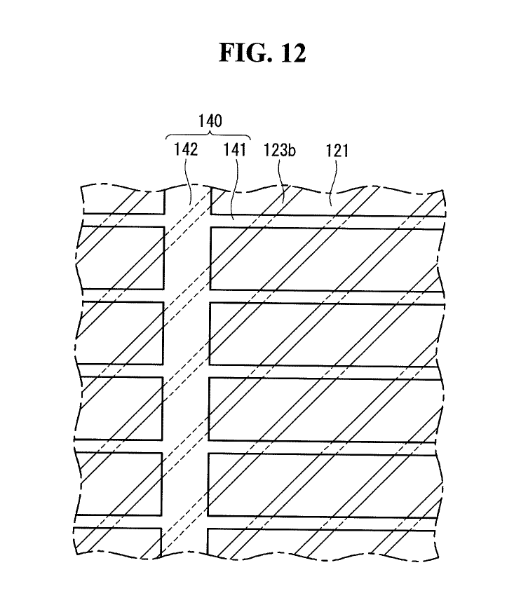

In another example of the solar cell according to the embodiment of the invention, configuration and components of a solar cell shown in FIGS. 11 and 12 are substantially the same as the solar cell shown in FIGS. 1 and 2 except heavily doped regions 123a and 123b.

As shown in FIG. 11, a heavily doped region 123a of the solar cell includes a portion (corresponding to the first portion 12a of FIG. 3) extending in the first direction. As shown in FIG. 12, a heavily doped region 123b of the solar cell includes a portion (corresponding to the second portion 12b of FIG. 3) extending in the second direction. In other words, the solar cell of FIG. 11 includes the plurality of heavily doped regions 123a, which extend in the first direction to be spaced apart from one another. Further, the solar cell of FIG. 12 includes the plurality of heavily doped regions 123b, which extend in the second direction to be spaced apart from one another.

As described above with reference to FIG. 3, each of the heavily doped regions 123a and 123b of FIGS. 11 and 12 extends in an oblique direction with respect to the side of the substrate 110 and forms a predetermined angle with the side of the substrate 110. The predetermined angle is greater than 0° and less than 90°.

As shown in FIGS. 11 and 12, because the plurality of front electrodes 141 extend across the heavily doped regions 123a and 123b, respectively, portions of the front electrodes 141 connected to the heavily doped regions 123a and 123b collect carriers moving through the heavily doped regions 123a and 123b, respectively.

A moving distance of carriers moving from the emitter region 121 to the front electrodes 141, the heavily doped regions 123a and 123b, or the front bus bars 142 decreases due to the heavily doped regions 123a and 123b, and various moving directions of carriers are obtained. Hence, an amount of carriers moving to the front electrode part 140 or the heavily doped regions 123a and 123b increases, and an amount of carriers output from the solar cell increases. When the solar cell includes one of the heavily doped regions 123a and 123b shown in FIGS. 11 and 12, the structure of the front electrode part 140 may have the structure shown in FIGS. 5, 6, 8, and 10.

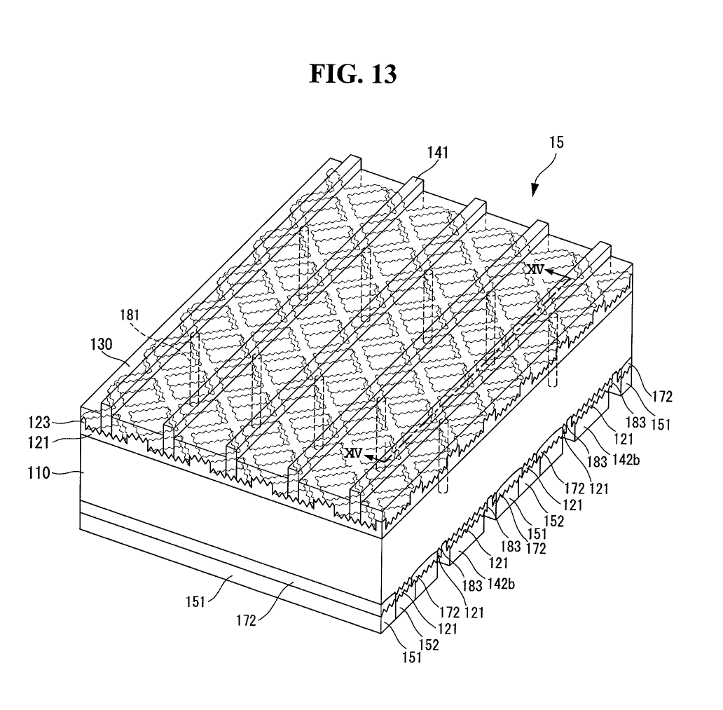

Hereinafter, various examples of the solar cell according to the embodiment of the invention are described with reference to FIGS. 13 to 22.

First, one example of the solar cell according to the embodiment of the invention is described with reference to FIGS. 13 to 15.

Structures and components identical or equivalent to those illustrated in FIGS. 1 and 2 are designated with the same reference numerals in the solar cell shown in FIGS. 13 to 15, and a further description may be briefly made or may be entirely omitted.

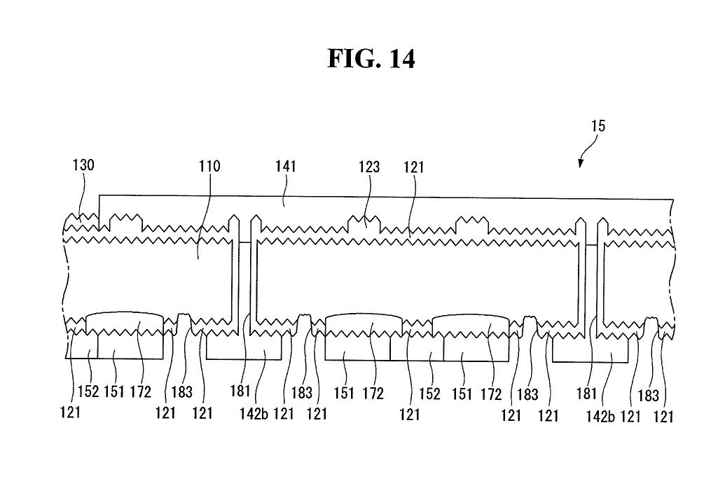

In a solar cell shown in FIGS. 13 and 14, a plurality of first bus bars are positioned on the back surface of the substrate, and the plurality of front electrodes positioned on the front surface of the substrate are connected to a plurality of second bus bars positioned on the back surface of the substrate using a plurality of via holes formed in the substrate.

In other words, as shown in FIGS. 13 and 14, a solar cell 15 includes a substrate 110 having a plurality of via holes 181, an emitter region 121 and a heavily doped region 123 which are positioned at the substrate 110, an anti-reflection layer 130 positioned on the emitter region 121 and the heavily doped region 123 which are positioned at an incident surface (i.e., a front surface) of the substrate 110, a plurality of front electrodes 141 positioned on the emitter region 121 and the heavily doped region 123 positioned at the front surface of the substrate 110, a back electrode 151 positioned on a back surface of the substrate 110, a plurality of front electrode bus bars (or a plurality of first bus bars) 142b which are positioned on the emitter region 121 positioned at the back surface of the substrate 110 in the via holes 181 and around the via holes 181 and are connected to the plurality of front electrodes 141, a plurality of back electrode bus bars (or a plurality of second bus bars) 152 which are positioned on the back surface of the substrate 110 and are connected to the back electrodes 151, and a back surface field (BSF) region 172, which adjoins the back electrode 151 and is positioned at the back surface of the substrate 110.

The impurity doped region of the solar cell 15 includes the emitter region 121 and the heavily doped region 123 which are different from each other in a sheet resistance, an impurity doping depth, and an impurity doping concentration. The heavily doped region 123 extends in first and second directions which cross each other and are oblique directions with respect to the side of the substrate 110. Thus, the heavily doped region 123 is positioned at the front surface of the substrate 110 in a lattice shape and forms predetermined angles (θ1 and θ2 as shown in FIG. 3) less than 90° with the side of the substrate 110.

The plurality of front electrodes 141 are positioned parallel to one another on the emitter region 121 and the heavily doped region 123 to be spaced apart from one another and extend in a third direction different from the extension direction (i.e., the first and second directions) of the heavily doped region 123.

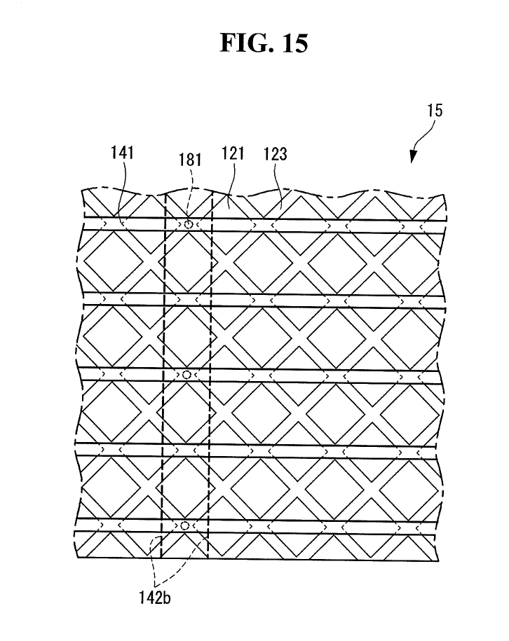

As described above, the third direction is a direction parallel to one side (for example, the upper side or the lower side in FIG. 15) of the substrate 110.

The plurality of front electrodes 141 collect carriers moving to the emitter region 121 and the heavily doped region 123, and transfer the carriers to the plurality of front electrode bus bars 142b connected to the front electrodes 141 through the via holes 181.

The plurality of front electrode bus bars 142b (as outlined in FIG. 15) are positioned on the back surface of the substrate 110 and extend parallel to one another in a direction crossing the front electrodes 141 positioned on the front surface of the substrate 110. Thus, the front electrode bus bars 142b have a stripe shape.

The plurality of via holes 181 are formed at crossings of the front electrodes 141 and the front electrode bus bars 142b in the substrate 110. At least one of the front electrode 141 and the front electrode bus bar 142b extends to at least one of the front and back surfaces of the substrate 110 through the via hole 181, and thus, the front electrode 141 and the front electrode bus bar 142b are connected to each other inside or around the via hole 181. In other words, the front electrodes 141 are connected to the front electrode bus bars 142b positioned opposite the front electrodes 141. As a result, the plurality of front electrodes 141 are electrically and physically connected to the plurality of front electrode bus bars 142b through the plurality of via holes 181.

The via holes 181 may be formed using a laser beam, etc., before or after the textured surface is formed.

When the impurity doped region including the emitter region 121 and the heavily doped region 123 is formed using the laser beam, the via holes 181 may be formed through changes in power, application time, etc., of the laser beam. In this instance, because the impurity doped regions 121 and 123 and the via holes 181 are formed through the same process, manufacturing time of the solar cell 15 is reduced.

The front electrode bus bars 142b output carriers transferred from the front electrodes 141 to the external device in the same manner as the front bus bars 142 of FIGS. 1 and 2.

The configuration of the back electrode bus bars 152 is substantially the same as the back bus bars 152 of FIGS. 1 and 2. Thus, the back electrode bus bars 152 are connected to the back electrode 151 and output carriers transferred through the back electrode 151 to the external device.

The front electrode bus bars 142b and the back electrode bus bars 152 contain a conductive material, for example, silver (Ag).

The front electrode bus bars 142b and the back electrode bus bars 152 are alternately positioned on the back surface of the substrate 110 based on the above-described structure. The solar cell 15 has a plurality of openings 183 which expose a portion of the back surface of the substrate 110 and surround the front electrode bus bars 142b, so as to prevent the front electrode bus bars 142b from being electrically connected to the back electrode 151 through the emitter region 121 positioned at the back surface of the substrate 110.

Namely, the plurality of openings 183 block the electrical connection between the front electrode bus bars 142b and the back electrode 151 which collect carriers of different conductive types, thereby preventing or reducing a recombination and/or a disappearance of carriers (for example, electrons and holes) of different conductive types respectively moving to the front electrode bus bars 142b and the back electrode 151.

In the embodiment of the invention, because the front electrode bus bars 142b are positioned on the back surface of the substrate 110, on which light is not incident, the incidence area of light increases. Hence, the efficiency of the solar cell 15 is improved.

Because the heavily doped region 123, which has the impurity doping concentration higher than the emitter region 121 and the sheet resistance less than the emitter region 121, performs the collection of carriers, a moving distance of carriers decreases. On the other hand, various moving directions (or routes) of carriers are obtained, and an amount of carriers moving from the emitter region 121 to the front electrode 141 greatly increases.

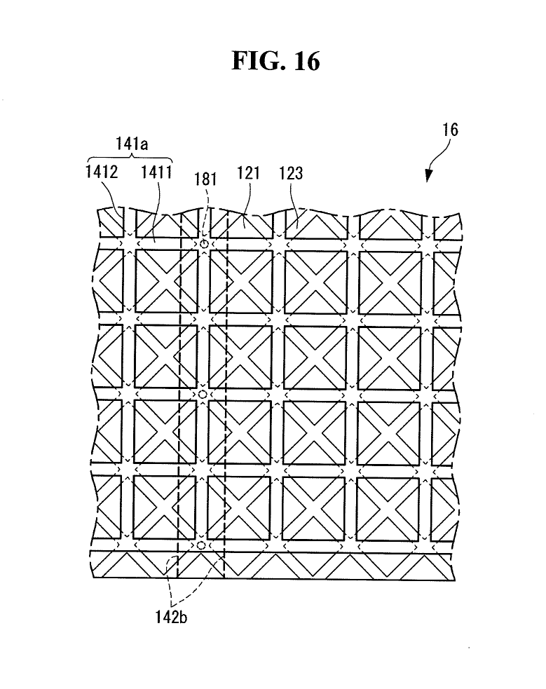

Another example of the solar cell, in which the plurality of front electrodes positioned on the front surface of the substrate are connected to the plurality of front electrode bus bars positioned on the back surface of the substrate through the plurality of via holes, is described below with reference to FIG. 16.

Since configuration of a solar cell 16 shown in FIG. 16 is substantially the same as the solar cell 15 shown in FIGS. 13 to 15 except the shape of the front electrode, a further description may be briefly made or may be entirely omitted.

The shape of the front electrode 141a positioned on the front surface of the substrate 110 in the solar cell 16 shown in FIG. 16 is substantially the same as the shape of the front electrode 141a in the solar cell 14 shown in FIG. 10. Namely, the front electrode 141a includes a plurality of first portions 1411 extending in a third direction and a plurality of second portions 1412 extending in a fourth direction crossing the third direction and is positioned on the front surface of the substrate 110 in a lattice shape. Crossings of the first and second portions 12a and 12b of the heavily doped region 123 overlap crossings of the first and second portions 1411 and 1412 of the front electrode 141a. Hence, an amount of carriers moving to the front electrode 141a through the heavily doped region 123 further increases.

A formation location of the via holes 181 in the substrate 110 is an overlap portion of the front electrode bus bars 142b positioned on the back surface of the substrate 110 and the front electrode 141a positioned on the front surface of the substrate 110. Because the front electrode bus bars 142b overlap the crossings of the first and second portions 1411 and 1412 of the front electrode 141a, the via holes 181 are formed at the crossings of the first and second portions 1411 and 1412 of the front electrode 141a. Hence, an amount of carriers transferred from the front electrode 141a to the front electrode bus bars 142b through the via holes 181 further increases.

Because the heavily doped region 123 having the lattice shape performs the collection of carriers, a moving distance of carriers decreases and a moving direction of carriers increases. Hence, an amount of carriers moving from the impurity doped regions 121 and 123 to the front electrode 141a greatly increases. Further, the formation area of the front electrode 141a collecting the carriers increases, and thus, an amount of carriers collected by the front electrode 141a further increases.

As described above, because the bus bars reducing the incidence area of light are not formed on the front surface of the substrate 110, the efficiency of the solar cell 16 is further improved.

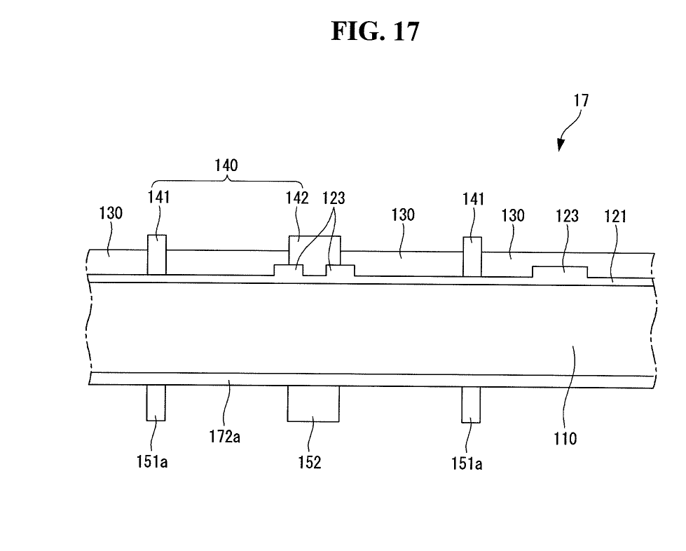

Another example of the solar cell according to the embodiment of the invention is described below with reference to FIG. 17.

A solar cell 17 shown in FIG. 17 is a bifacial solar cell, in which light is incident on both the front and back surfaces of the substrate.

Accordingly, as shown in FIG. 17, a plurality of back electrodes 151a are positioned on the back surface of the substrate 110 to be spaced apart from one another in the same manner as the front electrodes 141 shown in FIG. 4. Further, each of the back electrodes 151a extends in the same direction as the front electrodes 141. The back electrodes 151a and the front electrodes 141 may be aligned.

A plurality of front bus bars 142 extend in a direction crossing the front electrodes 141 on the front surface of the substrate 110, and a plurality of back bus bars 152 extend in a direction crossing the back electrodes 151a on the back surface of the substrate 110 in the same manner as FIGS. 1 and 2. The front bus bars 142 and the back bus bars 152 are positioned opposite each other with the substrate 110 interposed therebetween. The back bus bars 152 and the front bus bars 142 may be aligned. Before the back electrodes 151a and the back bus bars 152 are formed on the back surface of the substrate 110, a BSF region 172a may be formed. As shown in FIG. 17, the BSF region 172a is formed on the back surface of the substrate 110 and adjoins the plurality of back bus bars 152. Other configurations may be used for the BSF region 172a.

The solar cell 17 shown in FIG. 17 has the same configuration as the solar cell 11 shown in FIGS. 1 and 2, except the back electrodes 151a and the BSF region 172a formed on the back surface of the substrate 110.

Namely, an impurity doped region positioned at the front surface of the substrate 110 includes an emitter region 121 and a heavily doped region 123 having a lattice shape.

Accordingly, because the heavily doped region 123 having the lattice shape performs the collection of carriers, a moving distance of carriers decreases and a moving direction of carriers increases. Hence, an amount of carriers moving from the impurity doped regions 121 and 123 to the front electrode 141a greatly increases. Further, the formation area of the front electrode 141a collecting the carriers increases, and thus, an amount of carriers collected by the front electrode 141a further increases.

Because light is incident on both surfaces of the substrate 110, an amount of light incident on the substrate 110 increases. Hence, an amount of carriers produced by a p-n junction between a first conductive type region of the substrate 110 and the impurity doped regions 121 and 123 increases. As a result, the efficiency of the solar cell 17 is further improved.

Other examples of the bifacial solar cell 17 may have the structures of the front electrodes 141, the back electrode 151a, or the bus bars 141 and 152 illustrated in FIGS. 5 to 10.

For example, other examples of the bifacial solar cell 17 may have the structure, which does not include the front bus bars and the back bus bars and includes only the plurality of front electrodes 141 and the plurality of back electrodes 151a; the structure including the front electrode and the back electrode each having the lattice shape extending in the third and fourth directions, the plurality of front bus bars 142 positioned at an edge of the front surface of the substrate, and the plurality of back bus bars positioned at an edge of the back surface of the substrate; or the structure, which does not include the front bus bars and the back bus bars and includes the front electrode and the back electrode each having the lattice shape extending in the third and fourth directions.

Furthermore, other examples of the bifacial solar cell 17 may have the structure including the heavily doped regions 123a and 123b extending in the first or second direction along the side and the oblique line of the substrate as shown in FIGS. 11 and 12. In this instance, the structure of the front electrodes 141, the back electrode 151a, or the bus bars 141 and 152 may have one of the structures illustrated in FIGS. 5 to 10.

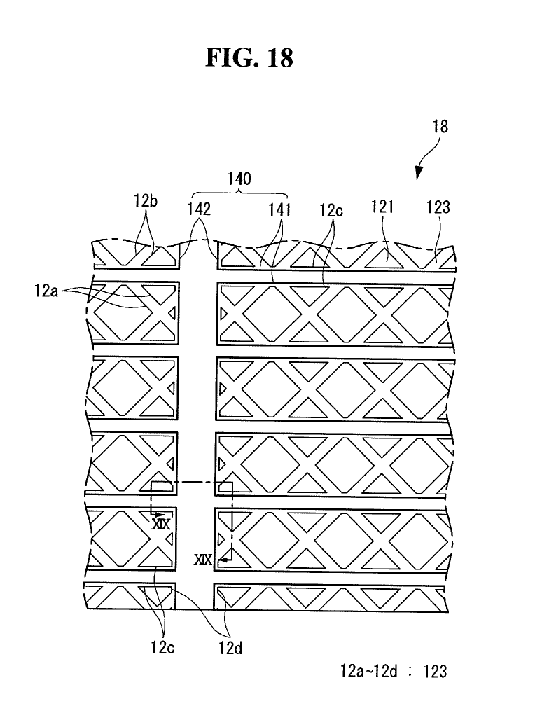

Another example of the solar cell according to the embodiment of the invention is described below with reference to FIGS. 18 to 20.

Each of solar cells 18 and 19 shown in FIGS. 18 to 20 has the same configuration as the solar cells 11 to 17 shown in FIGS. 1 to 17, except the structure of the emitter region.

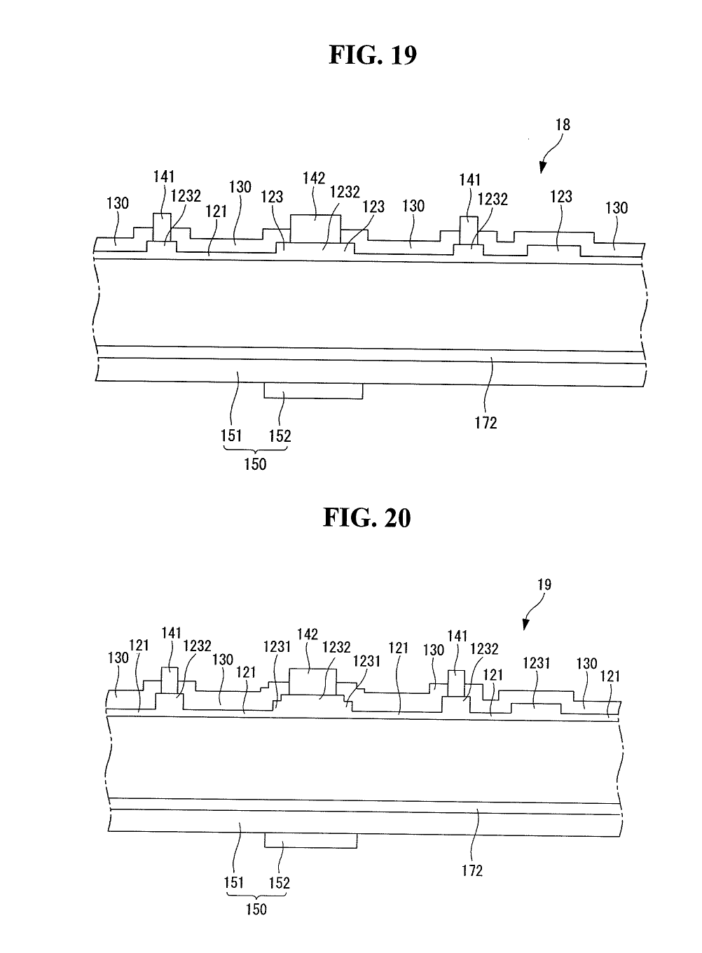

Namely, in the solar cell 18 shown in FIGS. 18 and 19, the heavily doped region 123 is positioned under the plurality of front electrodes 141 and the plurality of front bus bars 142.

The heavily doped region 123 includes first and second portions 12a and 12b, third portions 12c which are positioned under the front electrodes 141 and extend in the third direction along the front electrodes 141, and fourth portions 12d which are positioned under the front bus bars 142 and extend in the fourth direction along the front bus bars 142.

The third and fourth portions 12c and 12d of the heavily doped region 123 positioned under the front electrodes 141 and the front bus bars 142 may be the same as or different from the first and second portions 12a and 12b of the heavily doped region 123 in the sheet resistance, the impurity doping thickness, and the impurity doping concentration.

FIG. 19 illustrates that the sheet resistances, the impurity doping thicknesses, and the impurity doping concentrations of the third and fourth portions 12c and 12d of the heavily doped region 123 are substantially the same as those of the first and second portions 12a and 12b of the heavily doped region 123. FIG. 20 illustrates that the sheet resistances, the impurity doping thicknesses, and the impurity doping concentrations of the third and fourth portions 12c and 12d of the heavily doped region 123 are different from those of the first and second portions 12a and 12b of the heavily doped region 123.

As shown in FIG. 20, when the sheet resistances, the impurity doping thicknesses, and the impurity doping concentrations of the third and fourth portions 12c and 12d of the heavily doped region 123 are different from those of the first and second portions 12a and 12b of the heavily doped region 123, the first and second portions 12a and 12b are referred to as a first heavily doped region, and the third and fourth portions 12c and 12d are referred to as a second heavily doped region. In FIG. 20, a reference numeral ‘1231’ denotes the first heavily doped region, and a reference numeral ‘1232’ denotes the second heavily doped region.

The second heavily doped region 1232 has the impurity doping thickness and the impurity doping concentration, which are greater than the first heavily doped region 1231, and the sheet resistance less than the first heavily doped region 1231. The second heavily doped region 1232 is portions 12c and 12d which are positioned under the front electrodes 141 and the front bus bars 142 and adjoin the front electrodes 141 and the front bus bars 142. The first heavily doped region 1231 is portions 12a and 12b existing in an area of the substrate 110 on which the front electrodes 141 and the front bus bars 142 are not positioned. As shown in FIG. 18, the first heavily doped region 1231 and the second heavily doped region 1232 cross each other and are connected to each other at a crossing of the first and second heavily doped regions 1231 and 1232.

The second heavily doped region 1232 may be equally applied to the solar cells 12 to 17 shown in FIGS. 5 to 17. When the solar cells 12 to 17 do not include the plurality of front bus bars 142 or 142a, the second heavily doped region 1232 is positioned under the front electrodes 141 having the stripe shape extending in one direction or under the front electrodes 141a having the lattice shape extending in a cross direction and extends along the front electrodes 141 or 141a. The second heavily doped region 1232 does not exist in a non-formation portion of the front electrodes 141 or 141a.

Hence, the heavily doped region 123 or 1232 having the impurity doping thickness and the impurity doping concentration greater than the emitter region 121 is positioned under the front electrodes 141 or 141a and the front bus bars 142 or 142a. The heavily doped region 123 or 1232 adjoins the front electrodes 141 or 141a, the front bus bars 142 or 142a, or both.

The heavily doped region 123 or 1232 positioned under the front electrodes 141 or 141a, the front bus bars 142 or 142a, or both may be equally applied to the solar cells shown in FIGS. 11 and 12. Thus, the heavily doped region 123 or 1232 having the impurity doping thickness and the impurity doping concentration greater than the emitter region 121 is positioned under the front electrodes 141 or 141a and the front bus bars 142 or 142a.

Accordingly, a contact resistance between the heavily doped region 123 or 1232 and at least one of the front electrode 141 or 141a and the front bus bar 142 or 142a decreases, and the conductivity of the heavily doped region 123 or 1232 is greater than the conductivity of the emitter region 121. As a result, an amount of carriers moving from the heavily doped region 123 or 1232 to at least one of the front electrode 141 or 141a and the front bus bar 142 or 142a increases, and the movement of carriers is more easily performed.

As the impurity doping thickness of the heavily doped region 123 or 1232 adjoining at least one of the front electrode 141 or 141a and the front bus bar 142 or 142a increases, a shunt error, in which at least one of the front electrode 141 or 141a and the front bus bar 142 or 142a passes through the heavily doped region 123 or 1232 and contacts the first conductive type region of the substrate 110, is prevented from being generated when at least one of the front electrode 141 or 141a and the front bus bar 142 or 142a passes through the anti-reflection layer 130 and then contacts the heavily doped region 123 or 1232 positioned under the anti-reflection layer 130 in the thermal processing. Hence, a reduction in the efficiency of the solar cell is prevented.

Furthermore, when the first heavily doped region 1231 serving as a moving path of carriers has the impurity doping concentration lower than the second heavily doped region 1232 positioned under at least one of the front electrode 141 and the front bus bar 142, the recombination of carriers resulting from the high impurity doping concentration decreases in the first heavily doped region 1231. Hence, an amount of carriers lost by impurities decreases, and an amount of carriers moving from the first heavily doped region 1231 to at least one of the front electrode 141 and the front bus bar 142 decreases.

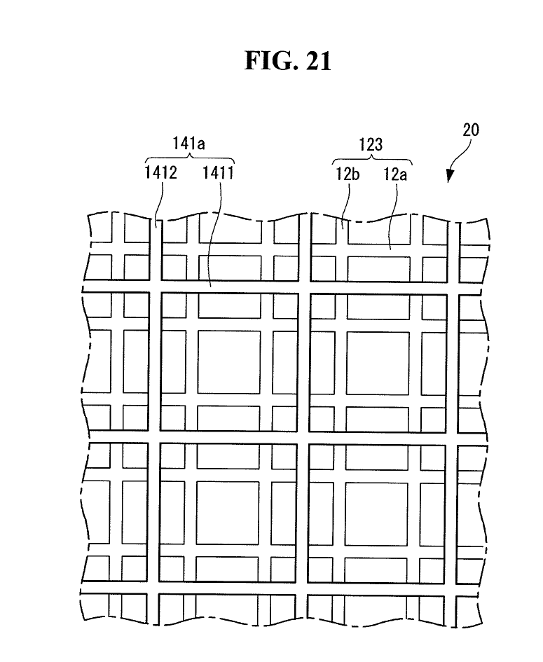

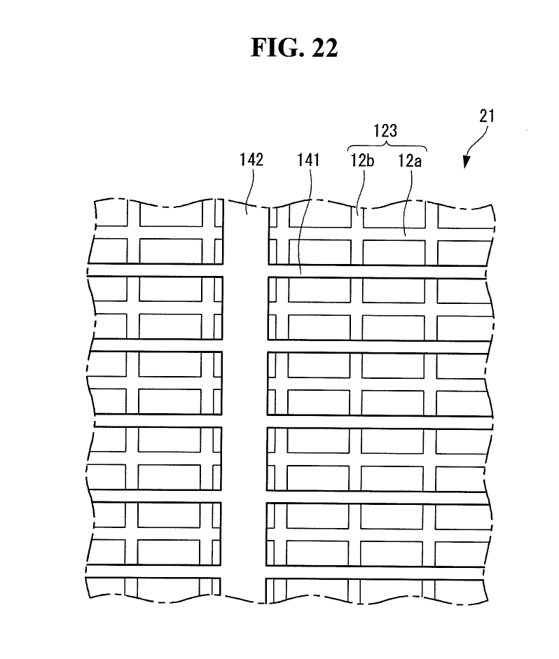

In solar cells 20 and 21 shown in FIGS. 21 and 22, the heavily doped region 123 has the lattice shape (or the first lattice shape) including the first and second portions 12a and 12b, and the front electrode 141a has the lattice shape (or the second lattice shape) including the first and second portions 1411 and 1412. However, the extension direction of the heavily doped region 123 is substantially the same as the extension direction of the front electrode 141a. Namely, the first portion 12a of the heavily doped region 123 extends in the same direction (i.e., the third direction) as the extension direction of the first portion 1411 of the front electrode 141a, and the second portion 12b of the heavily doped region 123 extends in the same direction (i.e., the fourth direction) as the extension direction of the second portion 1412 of the front electrode 141a. Hence, the first portion 12a of the heavily doped region 123 extends in the direction parallel to the first portion 1411 of the front electrode 141a, and the second portion 12b of the heavily doped region 123 extends in the direction parallel to the second portion 1412 of the front electrode 141a. Further, the first and second portions 12a and 12b of the heavily doped region 123 may be vertical to the left or right side of the substrate 110.

In the solar cell 20 shown in FIG. 21, the first portion 12a of the heavily doped region 123 and the first portion 1411 of the front electrode 141a, which extend in the third direction, are staggered by a predetermined distance in the fourth direction. Further, the second portion 12b of the heavily doped region 123 and the second portion 1412 of the front electrode 141a, which extend in the fourth direction, are staggered by a predetermined distance in the third direction. Thus, the first portion 12a of the heavily doped region 123 and the first portion 1411 of the front electrode 141a extending in the same direction (i.e., the third direction) do not overlap each other, and the second portion 12b of the heavily doped region 123 and the second portion 1412 of the front electrode 141a extending in the same direction (i.e., the fourth direction) do not overlap each other. As a result, the lattice shape of the heavily doped region 123 and the lattice shape of the front electrode 141a are staggered by a predetermined distance in the two directions (i.e., the third and fourth directions). In the embodiment of the invention, the lattice shape of the heavily doped region 123 and the lattice shape of the front electrode 141a are staggered in the two directions. However, the lattice shapes may be staggered in one direction (the third or fourth direction), or may be staggered in at least one direction of the two directions at a predetermined angle.

In other words, the first and second portions 12a and 12b of the heavily doped region 123 are positioned on parallel lines different from the first and second portions 1411 and 1412 of the front electrode 141a, respectively.

In the solar cell 21 shown in FIG. 22, similar to the solar cell 20 shown in FIG. 21, the first and second portions 12a and 12b of the heavily doped region 123 extend in the cross direction therebetween and are vertical to the left or right side of the substrate 110. The front electrode part 140 positioned on the heavily doped region 123 includes the plurality of front electrodes 141 and the plurality of front bus bars 142, which extend in the cross direction therebetween as shown in FIGS. 1 and 4. The first portion 12a of the heavily doped region 123 extends in the same direction (i.e., the third direction) as the extension direction of the plurality of front electrodes 141, and the second portion 12b of the heavily doped region 123 extends in the same direction (i.e., the fourth direction) as the extension direction of the plurality of front bus bars 142.

In the solar cells 20 and 21 shown in FIGS. 21 and 22, because the formation area of at least one of the heavily doped region 123 and the front electrode 141a or 141 positioned at the substrate 110 increases, the moving distance of carriers decreases. Hence, an amount of carriers moving to the heavily doped region 123 or the front electrode 141a or 141 increases.

The solar cell 20 shown in FIG. 21 may include the plurality of front bus bars 142a as shown in FIG. 7.

When the solar cells 20 and 21 shown in FIGS. 21 and 22 include the plurality of front bus bars 142a or 142, the heavily doped region 123 may further include the heavily doped regions 123 and 1232, which are positioned under the front electrodes 141a or 141 and entirely adjoin the front electrodes 141a or 141, as shown in FIGS. 18 to 20. In this instance, as described above, the heavily doped region 123 or 1232 positioned under the front electrodes 141a or 141 may have the impurity doping thickness and the impurity doping concentration equal to or greater than the heavily doped region 123 or 1231 positioned in the non-formation area of the front electrodes 141a or 141. Hence, the sheet resistance of the heavily doped region 123 or 1232 may be equal to or less than the sheet resistance of the heavily doped region 123 or 1231.

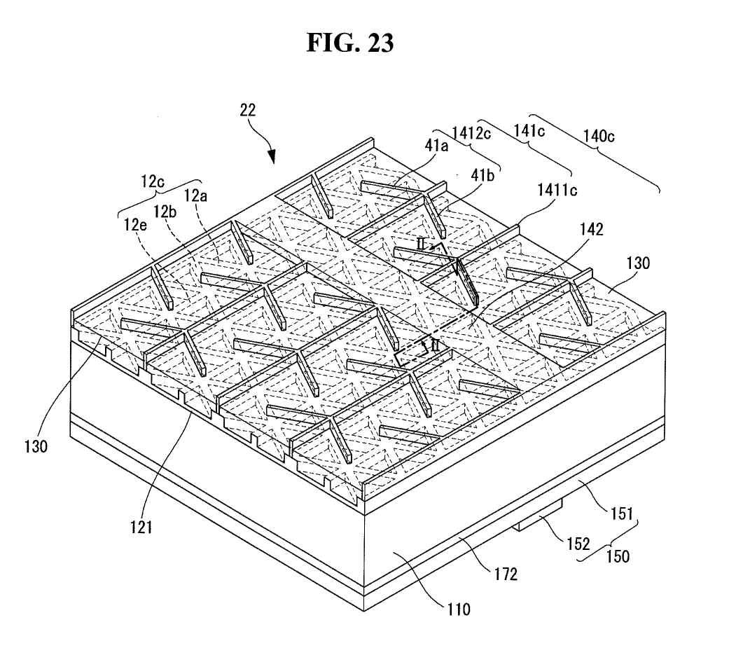

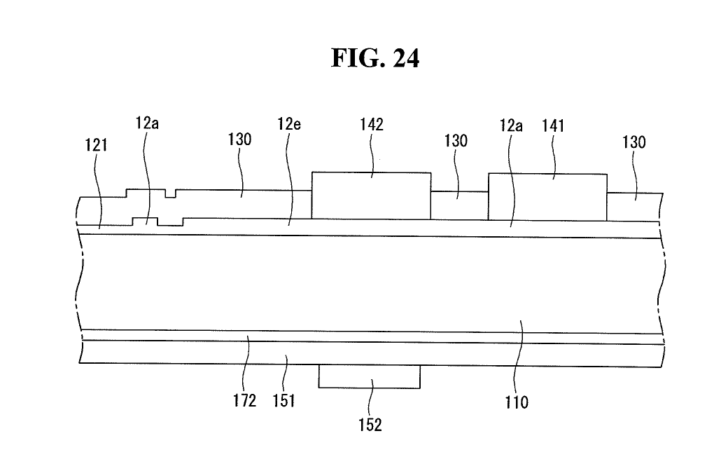

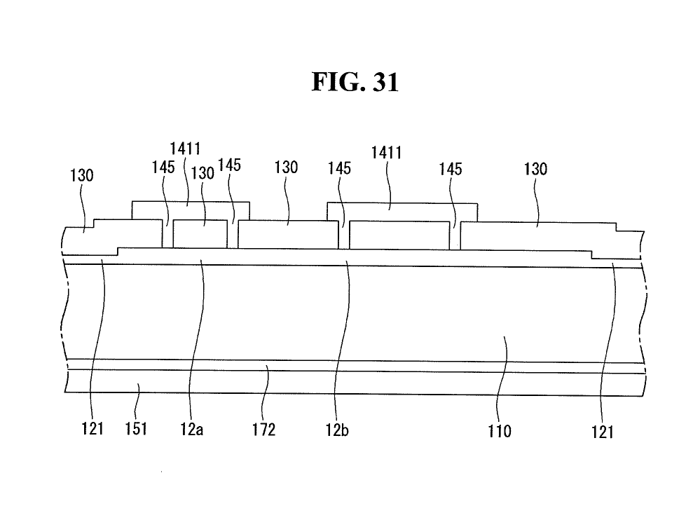

Hereinafter, a solar cell according to another embodiment of the invention is described with reference to FIGS. 23 to 31.

The solar cell shown in FIGS. 23 to 31 has the same configuration as the solar cells shown in FIGS. 1 to 10, except the front electrode part, more specifically, the shape of the front electrode and the shape of the heavily doped region. Thus, structures and components identical or equivalent to those illustrated in FIGS. 1 to 10 are designated with the same reference numerals in the solar cell shown in FIGS. 23 to 31, and a further description may be briefly made or may be entirely omitted.

As shown in FIG. 23, a heavily doped region 12c is an impurity doped region which is more heavily doped than the emitter region 121 with impurities of the same conductive type as the emitter region 121, as shown in FIG. 3. The heavily doped region 12c includes a first portion 12a extending in the first direction, a second portion 12b extending in the second direction, and a third portion 12e extending in the third direction different from the first and second directions. The third portion 12e extends in a straight line along a crossing of the first and second portions 12a and 12b.

Accordingly, the formation area of the heavily doped region 12c shown in FIG. 23 is greater than the heavily doped region 123 shown in FIGS. 1 to 4. Hence, the moving distance of carriers moving from the emitter region 121 to the heavily doped region 12c further decreases, and thus, a loss amount of carriers decreases.

In the solar cell shown in FIG. 23, the emitter region 121 surrounded by the heavily doped region 12c has a triangular shape.

A front electrode part 140c is connected to the emitter region 121 and the heavily doped region 12c and includes a plurality of front electrodes 141c and a plurality of front bus bars 142.

The plurality of front electrodes 141c are positioned on the heavily doped region 12c and are electrically and physically connected to the heavily doped region 12c. Thus, the plurality of front electrodes 141c collect carriers (for example, electrons) moving through the heavily doped region 12c.

Each of the front electrodes 141c does not extend only in one direction (i.e., the third direction) unlike the front electrodes shown in FIGS. 1 to 4. For example, as shown in FIGS. 23 to 25, each front electrode 141c includes a main branch 1411c and a plurality of subsidiary branches 1412c extending from the main branch 1411c in an oblique direction. The main branch 1411c extends in the extension direction (i.e., the third direction) of the third portion 12e of the heavily doped region 12c along the third portion 12e and is positioned on the third portion 12e to overlap the third portion 12e.

The plurality of subsidiary branches 1412c include a first subsidiary branch 41a and a second subsidiary branch 41b. The first subsidiary branch 41a extends from the main branch 1411c in the first direction and is positioned on the first portion 12a of the heavily doped region 12c to overlap the first portion 12a. The second subsidiary branch 41b extends from the main branch 1411c in the second direction and is positioned on the second portion 12b of the heavily doped region 12c to overlap the second portion 12b. The main branch 1411c of each front electrode 141c is positioned only on the third portion 12e of the heavily doped region 12c, the first subsidiary branch 41a of each front electrode 141c is positioned only on the first portion 12a of the heavily doped region 12c, and the second subsidiary branch 41b of each front electrode 141c is positioned only on the second portion 12b of the heavily doped region 12c.

The first and second subsidiary branches 41a and 41b extending from one main branch 1411c are separated from the adjacent front electrode 141c.

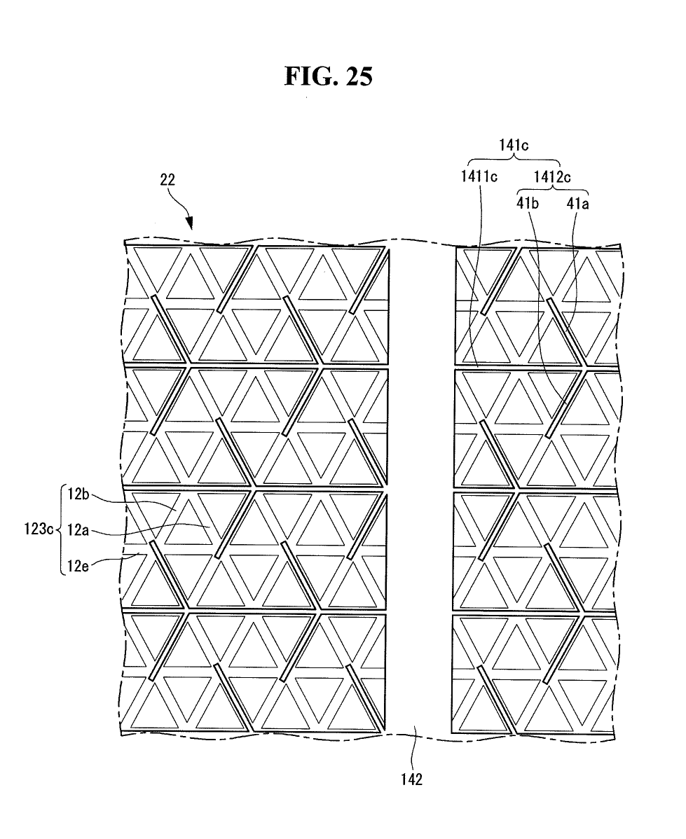

The first subsidiary branch 41a of the subsidiary branches 1412c extends along the first portion 12a of the heavily doped region 12c and extends to at least a portion of a crossing of the first and third portions 12a and 12e. The second subsidiary branch 41b of the subsidiary branches 1412c extends along the second portion 12b of the heavily doped region 12c and extends to at least a portion of a crossing of the second and third portions 12b and 12e. Thus, as shown in FIG. 25, the first and second subsidiary branches 41a and 41b adjoin a portion of a crossing of the first to third portions 12a, 12b, and 12e of the heavily doped region 12c, but may entirely adjoin the crossing of the first to third portions 12a, 12b, and 12e.

Because the first and second subsidiary branches 41a and 41b, which extend to the different portions, form a subsidiary branch pair, the subsidiary branch pair 41a and 41b extend in different oblique directions at the same position of the main branch 1411c, i.e., at the crossing of the first to third portions 12a, 12b, and 12e. Thus, each front electrode 141c includes a plurality of pairs of first and second subsidiary branches 41a and 41b, which extend in the different directions at each crossing of the first to third portions 12a, 12b, and 12e. Hence, the main branch 1411c and the first and second subsidiary branches 41a and 41b of the front electrode 141c are connected to crossings of the components 1411c, 41a and 41b.

In the embodiment of the invention, the front electrode 141c extends in the first to third directions in the same manner as the heavily doped region 12c and is positioned only on the heavily doped region 12c.

In the two adjacent front electrodes 141c, one (for example, the first subsidiary branch 41a) of the first and second subsidiary branches 41a and 41b extending from the main branch 1411c of one front electrode 141c and one (for example, the second subsidiary branch 41b) of the second and first subsidiary branches 41b and 41a extending from the main branch 1411c of the other front electrode 141c are alternately positioned between the main branches 1411c of the two adjacent front electrodes 141c.

Because the front electrode 141c includes the plurality of subsidiary branches 1412c as well as the main branch 1411c, the formation area of the front electrode 141c increases by the formation area of the subsidiary branches 1412c. Further, because the first subsidiary branch 41a of one of the two adjacent front electrodes 141c and the second subsidiary branch 41b of the other front electrode 141c are staggered between the main branches 1411c of the two adjacent front electrodes 141c, the moving distance of carriers moving from the heavily doped region 12c to the front electrodes 141c further decreases.

As described above, the first and second subsidiary branches 41a and 41b adjoin all of the crossings of the plurality of portions (for example, the first to third portions 12a, 12b, and 12e) of the heavily doped region 12c which extend from the main branch 1411c in the different directions (for example, the first to third directions). Because the crossings of the first to third portions 12a, 12b, and 12e are collection areas of carriers moving along the first to third portions 12a, 12b, and 12e of the heavily doped region 12c, most of carriers moving along the heavily doped region 12c exist at the crossings. As described above, because the first and second subsidiary branches 41a and 41b extend to the crossings of the heavily doped region 12c, at which more carriers exists than in other portions of the heavily doped region 12c, an amount of carriers moving to the main branch 1411c through the first and second subsidiary branches 41a and 41b increases. Hence, an amount of carriers collected by the front electrodes 141c through the heavily doped region 12c increases.

Because the plurality of front electrodes 141 are directly connected to a portion of the heavily doped region 12c, the anti-reflection layer 130 does not exist under the plurality of front electrodes 141.

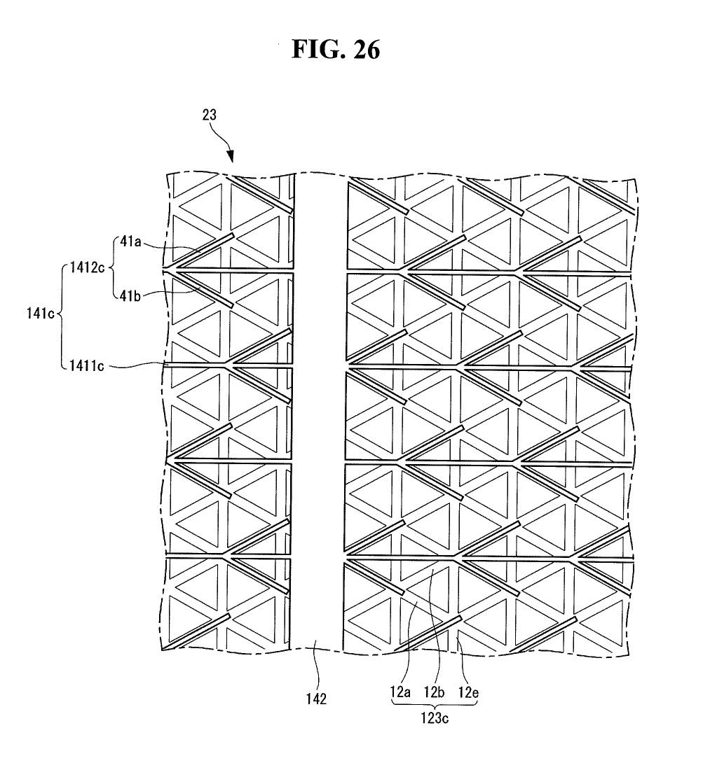

However, in an alternative example, the main branch 1411c of each front electrode 141c adjoins the emitter region 121 as well as the heavily doped region 12c. For example, in a solar cell 23 shown in FIG. 26, the main branch 1411c of each front electrode 141c extends along the crossings of the first to third portions 12a, 12b, and 12e of the heavily doped region 12c. However, the main branch 1411c is not positioned on the third portion 12e and extends along not the third portion 12e but a direction vertical to the third portion 12e. In this instance, the main branch 1411c adjoins the emitter region 1212 in the front surface of the substrate 110 excluding the crossings of the first to third portions 12a, 12b, and 12e and crossings of the third portion 12e and the main branch 1411c. Further, because the first and second subsidiary branches 41a and 41b, which extend to the different portions, form a subsidiary branch pair, the subsidiary branch pair 41a and 41b extend in different oblique directions at the same position of the main branch 1411c, i.e., at the crossing of the first to third portions 12a, 12b, and 12e. Thus, each front electrode 141c includes a plurality of pairs of first and second subsidiary branches 41a and 41b, which extend in the different directions at each crossing of the first to third portions 12a, 12b, and 12e. Hence, the main branch 1411c and the first and second subsidiary branches 41a and 41b of the front electrode 141c are connected to crossings of the components 1411c, 41a and 41b.

In this instance, the heavily doped region 12c extends in various directions, for example, the first to third directions, and at least a portion of each of the first to third portions 12a, 12b, and 12e of the heavily doped region 12c extending in one of the first to third directions is positioned not to overlap the front electrode part 140c. Hence, the moving path of carriers moving from the emitter region 121 to the heavily doped region 12c or the front electrode part 140c is further varied or increased, and the moving distance of carriers further decreases. As a result, an amount of carriers lost during the movement of carriers to the heavily doped region 12c or the front electrode part 140c decreases, and an amount of carriers transferred to the front electrode part 140c increases.

Because each front bus bar 142 has to collect carriers collected by the front electrodes 141c crossing the front bus bar 142 and has to transfer the carriers in a desired direction, a width of each front bus bar 142 is greater than a width of the main branch 1411c of each front electrode 141c.

In the solar cells shown in FIGS. 23 to 26, the subsidiary branches 1412c extending from the main branch 1411c of the front electrode 141c include the plurality of first and second subsidiary branches 41a and 41b. However, the subsidiary branches 1412c may be at least one of the first and second subsidiary branches 41a and 41b.

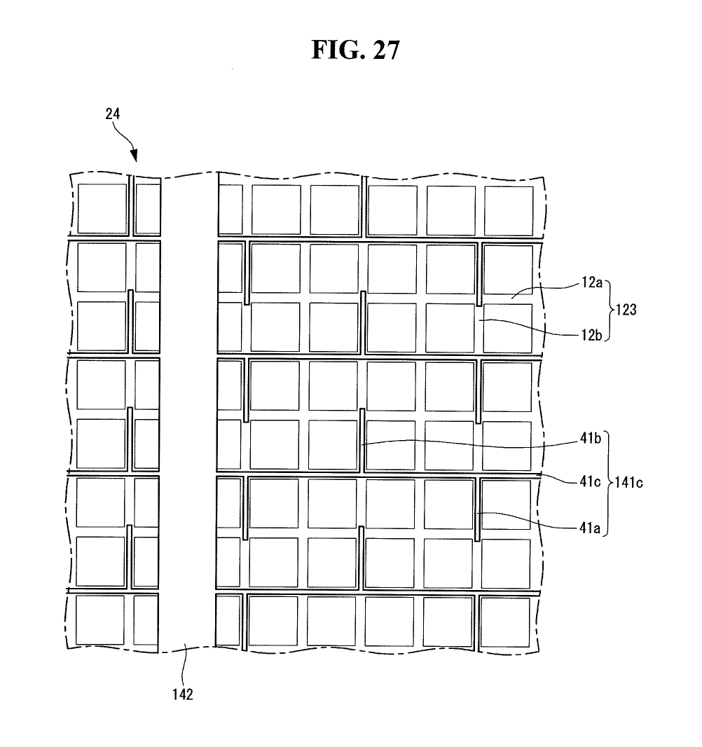

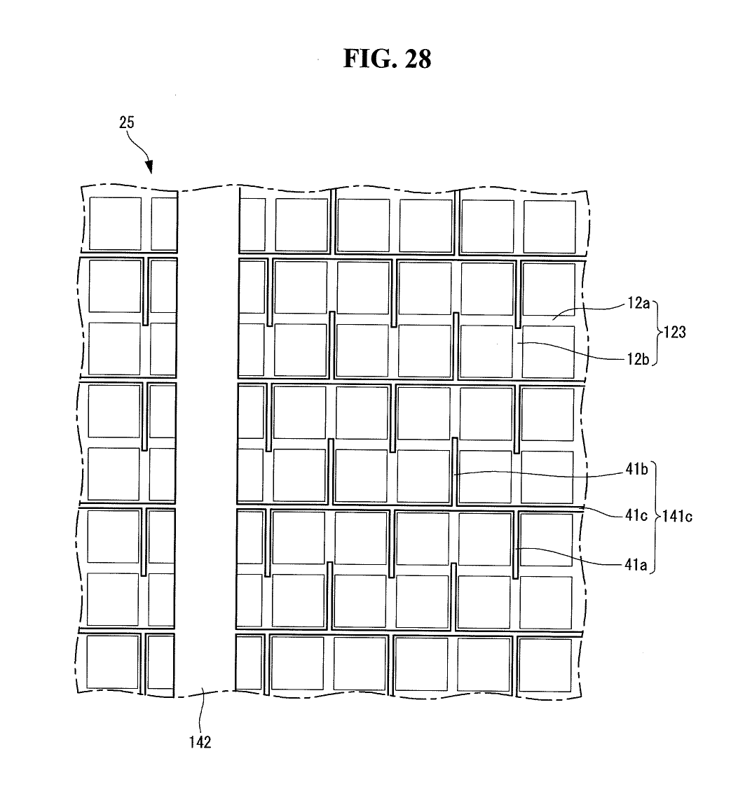

Hereinafter, solar cells 24 and 25 according to the embodiment of the invention are described with reference to FIGS. 27 and 28.

The solar cells 24 and 25 shown in FIGS. 27 and 28 have the same configuration as the solar cell 22 shown in FIGS. 23 to 25, except the shape of the heavily doped region. The heavily doped region shown in FIGS. 27 and 28 has the same shape as the heavily doped region 123 shown in FIGS. 21 and 22. Thus, the heavily doped region 123 includes a first portion 12a extending in the third direction and a second portion 12b extending in the fourth direction. The first and second portions 12a and 12b of the heavily doped region 123 may be vertical to the left or right side of the substrate 110.

Unlike the solar cell shown in FIGS. 21 and 22, the plurality of front electrodes 141c are positioned only on the heavily doped region 123 and extend along a portion of the heavily doped region 123.

Each front electrode 141c includes a main branch 41c and a plurality of first and second subsidiary branches 41a and 41b. The main branch 41c is positioned on the first portion 12a of the heavily doped region 123 and extends along the first portion 12a in the third direction. The plurality of first and second subsidiary branches 41a and 41b are positioned on the second portion 12b of the heavily doped region 123 and extend from the main branch 41c along the second portion 12b in different directions.

The plurality of subsidiary branches 41a and 41b extending from the main branch 41c of one front electrode 141c are connected to the plurality of subsidiary branches 41a and 41b extending from the main branch 41c of other front electrode 141c. Further, the first and second subsidiary branches 41a and 41b of one front electrode 141c extend in the same direction (i.e., the fourth direction) and are positioned on the opposite sides of the main branch 41c. Because the plurality of first and second subsidiary branches 41a and 41b of one front electrode 141c are alternately positioned, the first and second subsidiary branches 41a and 41b of the one front electrode 141c extend in the opposite directions. Further, the first and second subsidiary branches 41a and 41b extend until they reach the second portion 12b of the heavily doped region 123 existing between the main branches 41c of the two adjacent front electrodes 141c.

The solar cell 25 shown in FIG. 28 includes a heavily doped region 123, which includes a first portion 12a extending in the third direction and a second portion 12b extending in the fourth direction and has a lattice shape, and a plurality of front electrodes 141c, each of which includes a main branch 41c extending in the third direction and a plurality of first and second subsidiary branches 41a and 41b extending in the fourth direction, in the same manner as the solar cell 24 shown in FIG. 27.

Because a distance between the two adjacent first and second subsidiary branches 41a and 41b of each front electrode 141c may be adjusted, a distance between the two adjacent first and second subsidiary branches 41a and 41b in the solar cell 25 shown in FIG. 28 may be different from a distance between the two adjacent first and second subsidiary branches 41a and 41b in the solar cell 24 shown in FIG. 27.

For example, as shown in FIG. 27, because the first and second subsidiary branches 41a and 41b of the front electrodes 141c extend to all of crossings of the first and second portions 12a and 12b of the heavily doped region 123, the first and second subsidiary branches 41a and 41b may be positioned at all of crossings of the front electrodes 141c and the heavily doped region 123. As shown in FIG. 28, the plurality of first and second subsidiary branches 41a and 41b may be alternately positioned at a predetermined distance, for example, every two crossings of the front electrodes 141c and the heavily doped region 123. As described above, the first and second subsidiary branches 41a and 41b of one front electrode 141c are alternately positioned on the opposite sides of the main branch 41c.

Accordingly, as described above, because the formation area of the plurality of front electrodes 141c increases due to the formation of the plurality of front electrodes 141c including the plurality of first and second subsidiary branches 41a and 41b, the moving distance of carriers moving from the emitter region 121 or the heavily doped region 123 to the front electrodes 141c decreases. Hence, a loss amount of carriers during the movement of carriers from the emitter region 121 or the heavily doped region 123 to the front electrodes 141c decreases.

As shown in FIGS. 27 and 28, the first and second subsidiary branches 41a and 41b of the front electrode 141c extend to the crossings of the plurality of portions (for example, the first and second portions 12a and 12b) of the heavily doped region 123. Hence, the first and second subsidiary branches 41a and 41b of the front electrodes 141c are positioned at the crossings of the first and second portions 12a and 12b of the heavily doped region 123, in which all of carriers moving along the first and second portions 12a and 12b are collected. Thus, the collection of carriers from the heavily doped region 123 to the front electrodes 141c is easily performed, and an amount of carriers collected by the front electrodes 141c increases. The first and second subsidiary branches 41a and 41b of one front electrode 141c are separated from the first and second subsidiary branches 41a and 41b of the front electrode 141c adjacent to the one front electrode 141c.

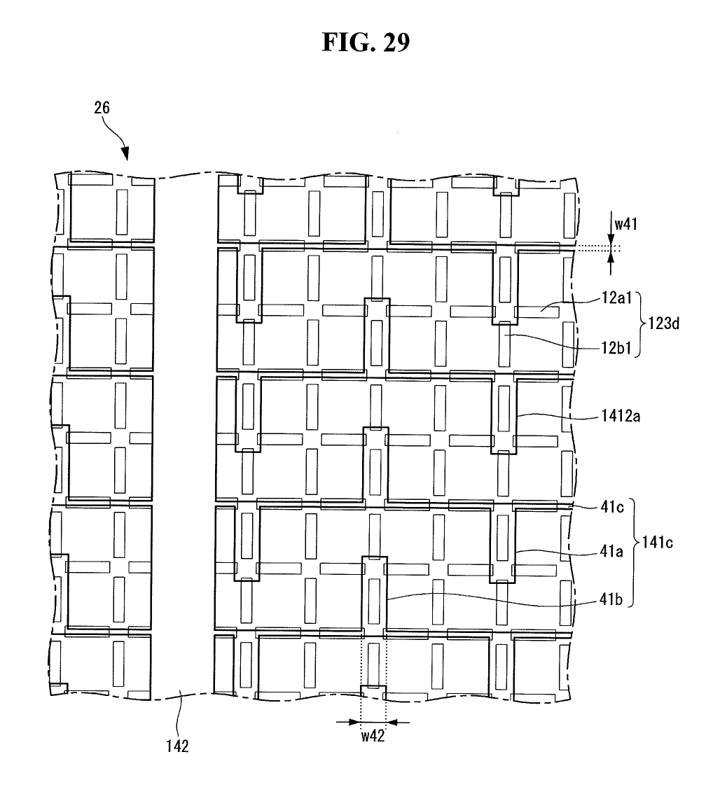

Hereinafter, a solar cell 26 according to the embodiment of the invention is described with reference to FIG. 29.

Since configuration of the solar cell 26 shown in FIG. 29 is substantially the same as the solar cell 24 shown in FIG. 27 except the shape of the heavily doped region, a further description may be briefly made or may be entirely omitted.

As shown in FIG. 29, the solar cell 26 includes a heavily doped region 123d and a front electrode part including a plurality of front electrodes 141c and a plurality of front bus bars 142. The heavily doped region 123d includes a plurality of portions, for example, a plurality of first portions 12a1 and a plurality of second portions 12b1, which extend in different directions, for example, the third and fourth directions. Each of the plurality of front electrodes 141c includes a main branch 41c extending in the third direction and a plurality of first and second subsidiary branches 41a and 41b, which extend from the main branch 41c in the fourth direction and are positioned on the opposite sides of the main branch 41c. The plurality of front bus bars 142 extend in the fourth direction, cross the front electrodes 141c, and are connected to the front electrodes 141c. Thus, the shape of the front electrode 141c positioned on the heavily doped region 123d is substantially the same as the shape of the front electrode 141c shown in FIG. 27, except a width W41 of the main branch 41c and a width W42 of the first and second subsidiary branches 41a and 41b.

Unlike the solar cell 24 shown in FIG. 27, the first and second portions 12a1 and 12b1 of the heavily doped region 123d extending in the different directions do not cross each other and are separated from each other. Therefore, the heavily doped region 123d does not have a cross area of the first and second portions 12a1 and 12b1, and the first and second portions 12a1 and 12b1 are not connected to each other.

More specifically, the plurality of first portions 12a1 of the heavily doped region 123d positioned on the same line are separated from one another and extend parallel to one another in the third direction. Further, the plurality of second portions 12b1 of the heavily doped region 123d positioned on the same line are separated from one another and extend parallel to one another in the fourth direction. Thus, the main branch 41c of the front electrode 141c adjoins the plurality of first portions 12a1 which are positioned parallel to one another along the third direction, and the front electrode 141c and the emitter region 121 are connected to each other between the two adjacent first portions 12a1.

The first and second subsidiary branches 41a and 41b of the front electrode 141c adjoin the second portions 12b1 of the heavily doped region 123d extending along the fourth direction.

Each of the plurality of first and second subsidiary branches 41a and 41b of the front electrode 141c extends to a region, in which the first portions 12a1 and the second portions 12b1 are gathered, and adjoins both the first and second portions 12a1 and 12b1 in a gather region (e.g., a region where the first and second portions 12a1 and 12b1 approach but do not cross). The first and second subsidiary branches 41a and 41b are separated from each other. The first and second subsidiary branches 41a and 41b collect carriers moving through the first and second portions 12a1 and 12b1 and then transfer the carriers to the front electrode 141c. Hence, the movement of carriers to the front electrodes 141c is easily and efficiently performed.

The structure of the heavily doped region 123d shown in FIG. 29, which includes the plurality of portions extending in the different directions and does not have a cross area between at least two of the plurality of portions, may be applied to the heavily doped regions 123 and 12c including the plurality of portions 12a to 12e. In this instance, because the front electrodes 141, 141a and 141c are positioned in the gather region of the plurality of portions 12a, 12b and 12e and adjoins the plurality of portions 12a, 12b and 12e, carriers gathered in the plurality of portions 12a, 12b and 12e of the heavily doped regions 123 and 12c are easily collected by the front electrode 141, 141a and 141c. Further, the first and second subsidiary branches 41a and 41b of one front electrode 141c are separated from the front electrode adjacent to the one front electrode 141c.

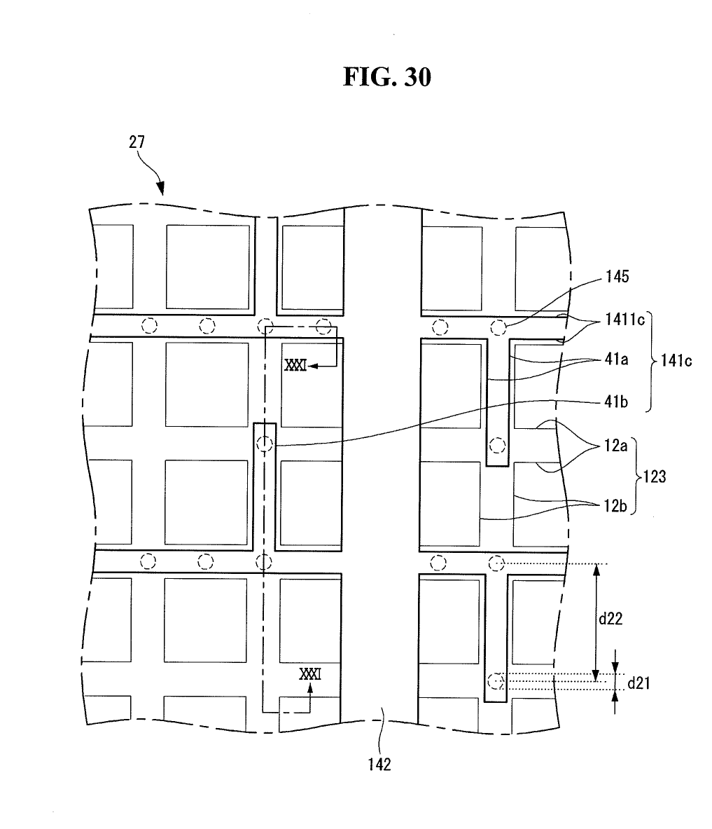

Hereinafter, a solar cell 27 according to the embodiment of the invention is described with reference to FIG. 30.

Since configuration of the solar cell 27 shown in FIG. 30 is substantially the same as the solar cell 24 shown in FIG. 27 except the connection structure between the heavily doped region and the front electrodes, a further description may be briefly made or may be entirely omitted.

As shown in FIG. 30, the solar cell 27 includes a front electrode part including a plurality of front electrodes 141c and a plurality of front bus bars 142, and a heavily doped region 123. Each of the plurality of front electrodes 141c includes a main branch 1411c extending in the third direction and a plurality of first and second subsidiary branches 41a and 41b which extend from the main branch 1411c in the fourth direction and are positioned on the opposite sides of the main branch 1411c. The plurality of front bus bars 142 extend in the fourth direction, cross the front electrodes 141c, and are connected to the front electrodes 141c. The heavily doped region 123 includes a first portion 12a extending in the third direction and a second portion 12b which extends in the fourth direction and is connected to a crossing of the first portion 12a and the second portion 12b.

Unlike the front electrodes 141c shown in FIG. 27 which entirely adjoin the heavily doped region 123 underlying the front electrodes 141c, the front electrodes 141c shown in FIG. 30 are selectively or partially connected to the heavily doped region 123 underlying the front electrodes 141c.

For example, as shown in FIG. 30, the main branch 1411c and the first and second subsidiary branches 41a and 41b of each front electrode 141c include a plurality of contact portions 145 directly contacting the heavily doped region 123 underlying the front electrode 141c. A maximum diameter d21 of each contact portion 145 may be about 100 μm, for example, about 90 μm to 110 μm, and a distance d22 between the middle portions of the two adjacent contact portions 145 may be about 400 μm to 1 mm.

Accordingly, only the plurality of contact portions 145 of the front electrode 141c contact the heavily doped region 123. As shown in FIG. 30, a portion of the front electrode 141c, which excludes the plurality of contact portions 145 and is not directly connected to the heavily doped region 123, is positioned on the anti-reflection layer 130 and adjoins the anti-reflection layer 130. Further, because the plurality of front bus bars 142 including a portion crossing the front electrodes 141c do not include the plurality of contact portions 145, all of the plurality of front bus bars 142 do not contact the heavily doped region 123. Thus, all of the plurality of front bus bars 142 are positioned on the anti-reflection layer 130 and adjoin the anti-reflection layer 130.

Hence, the anti-reflection layer 130 is positioned under a portion of each front electrode 141c and under all of the front bus bars 142.

The plurality of contact portions 145 of the main branch 1411c of each front electrode 141c include the plurality of contact portions 145 formed at crossings of the first and second portions 12a and 12b of the heavily doped region 123 and the plurality of contact portions 145 formed only on the first portions 12a of the heavily doped region 123. Further, the plurality of contact portions 145 of the first and second subsidiary branches 41a and 41b of each front electrode 141c are formed at the crossings of the first and second portions 12a and 12b of the heavily doped region 123.

Accordingly, carriers moving along the heavily doped region 123 move to the front electrodes 141c through the plurality of contact portions 145 adjoining the heavily doped region 123 and then are collected by the plurality of front bus bars 142.

Because the plurality of contact portions 145 are positioned at the crossings of the first and second portions 12a and 12b of the heavily doped region 123 in which an amount of carriers moving through the first and second portions 12a and 12b of the heavily doped region 123 is more than other area of the heavily doped region 123, carriers moving from the heavily doped region 123 to the front electrodes 141c are more efficiently collected.

As shown in FIG. 30, each contact portion 145 is an opening which is formed in the anti-reflection layer 130 and exposes a portion of the heavily doped region 123 underlying the anti-reflection layer 130. The contact portions 14 have a circle shape and are spaced apart from one another at a uniform distance. Alternatively, the contact portions 145 may have various shapes, such as an oval, a triangle, a rectangle, and a polygon, and may be spaced apart from one another at a non-uniform distance.

As described above, because only a portion of the front electrode 141c contacts the heavily doped region 123 formed of the semiconductor material through the contact portions 145 (i.e., the entire front electrode 141c does not contact the heavily doped region 123), a contact area between the heavily doped region 123 formed of silicon and the front electrode part including the front electrodes 141c formed of metal, for example, silver (Ag) decreases. Because the plurality of front bus bars 142, which have the width much greater than the front electrodes 141c and occupy a large area of the front surface of the substrate 110, are positioned on the anti-reflection layer 130, the formation area of the front electrode part, which does not directly adjoin the heavily doped region 123, further increases.

In general, when electric current is generated by the photoelectric effect, electric current flows in a contact portion between the metal material and the semiconductor material, even in a state where light is not irradiated, because of causes such as a thermal factor and the insulation failure. This electric current is referred to as a dark current. As a contact area between the metal material and the semiconductor material decreases, an amount of dark current generated in the contact portion decreases.

In the solar cell using the photoelectric effect to convert light into electricity, as an amount of dark current increases, an open-circuit voltage corresponding to an output voltage of the solar cell decreases. In the solar cell 30 according to the embodiment of the invention, a contact area between the metal material (i.e., the front electrode part) and the semiconductor material (i.e., the heavily doped region) decreases. Thus, the generation of dark current decreases, and the output voltage increases. As a result, the efficiency of the solar cell 30 increases.

Various methods for bringing a portion of the heavily doped region 123 into contact with a portion of the front electrode 141c are described below.

Impurities of a second conductive type, for example, n-type or p-type are diffused into the substrate 110 of a first conductive type, for example, p-type or n-type to form an impurity region at the surface of the substrate 110. A portion of the impurity region is then removed through the etching, etc., to form the emitter region 121 and the heavily doped region 123 including the first and second portions 12a and 12b.

Next, the anti-reflection layer 130 is formed on the emitter region 121 and the heavily doped region 123 formed at the front surface of the substrate 110 using a plasma enhanced chemical vapor deposition (PECVD) method, etc.

Next, an etching paste is selectively coated on the anti-reflection layer 130, and a portion of the anti-reflection layer 130, on which the etching paste is coated, is removed. The anti-reflection layer 130 is then cleaned, and a plurality of openings are formed in a corresponding portion of the anti-reflection layer 130. Alternatively, an etch stop mask is formed in a corresponding portion of the anti-reflection layer 130, and then a desired portion of the anti-reflection layer 130 is removed using a wet etching method or a dry etching method, to thereby form a plurality of openings. The heavily doped region 123 is partially exposed through the plurality of openings.

Next, a front electrode part paste is printed on the anti-reflection layer 130 and the portion of the heavily doped region 123 exposed through the plurality of openings using a screen printing method and is dried or plated to form the front electrode part. Hence, a portion of the front electrode part, in which the plurality of openings are positioned, forms the contact portions 145 and directly adjoins the heavily doped region 123. The remaining portion of the front electrode part, in which the openings are not positioned, is positioned on the anti-reflection layer 130.

Because the plurality of openings correspond to the plurality of contact portions 145, desired portions of the main branch 1411c and the first and second subsidiary branches 41a and 41b of each front electrode 141c contact the heavily doped region 123 through the openings to thereby form the plurality of contact portions 145.

In another method, after the anti-reflection layer 130 is formed, a front electrode part pattern having a desired shape (for example, the shape of the front electrode part) is formed on the anti-reflection layer 130 using the screen printing method or a plating method. Then, a laser beam, etc., is selectively irradiated onto the front electrode part pattern. Hence, a portion of the front electrode part pattern, onto which the laser beam is irradiated, contacts the heavily doped region 123, and the plurality of contact portions 145 are formed in the irradiation portion of the laser beam.

In another example of the method for forming the front electrode part including the plurality of contact portions 145, after the anti-reflection layer 130 is formed, a through type metal paste (for example, an etching paste containing a metal), which can pass through the anti-reflection layer 130 and can contact the heavily doped region 123, is coated on the anti-reflection layer 130 positioned at a location corresponding to the contact portions 145 through a thermal process. A non-through type metal paste (for example, a non-etching paste containing a metal) is coated on the through type metal paste and a portion of the anti-reflection layer 130 to form a front electrode part pattern. The thermal process is performed on the front electrode part pattern. Hence, the anti-reflection layer 130 in a coated portion of the through type metal paste is removed by an operation of the through type metal paste, and the plurality of contact portions 145 contacting the heavily doped region 123 are formed. As a result, the front electrode part including the plurality of contact portions 145 is formed.

As described above, after the front electrode part including the plurality of contact portions 145 contacting the heavily doped region 123 is formed, the back electrode part 150 including the back electrode 151 and the plurality of back bus bars 152 and the BSF region 172 are formed on the back surface of the substrate 110 using the screen printing method or the thermal process.

In the embodiment of the invention, the formation order of the front electrode part 140c and the back electrode part 150 may vary.

The configuration of the solar cell 27, in which each front electrode 141c selectively or partially contacts the heavily doped region 123 to form the local contact between the front electrodes 141c and the heavily doped region 123, may be applied to all of the above-described solar cells 11 to 26 according to the embodiment of the invention.

In the embodiment of the invention, the front bus bars 142 do not contact the heavily doped region 123 and are positioned on the anti-reflection layer 130. However, the front bus bars 142 may selectively or partially contact the heavily doped region 123 to form the local contact.

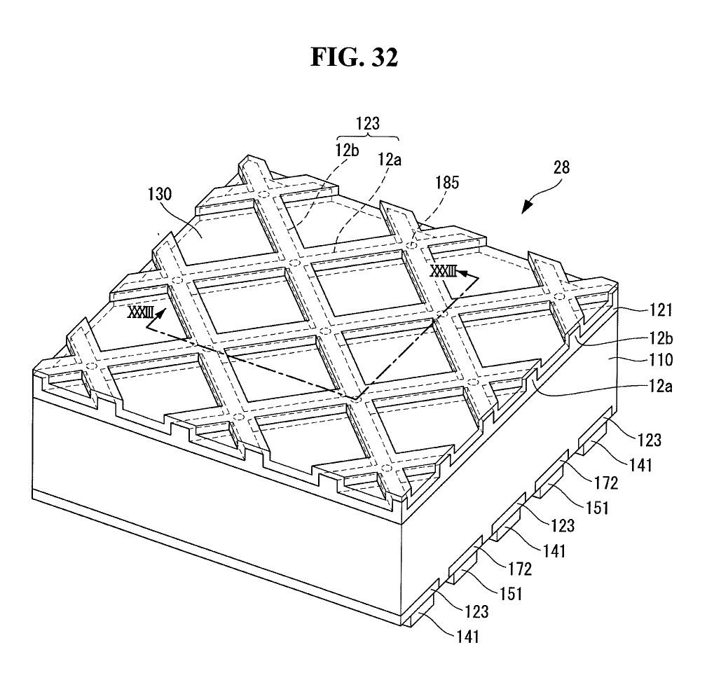

Hereinafter, a solar cell 28 including a heavily doped region having the same shape as the heavily doped region shown in FIG. 3 is described with reference to FIGS. 32 to 35.

Since the emitter region 121 and the heavily doped region 123, which are formed at the front surface of the substrate 110, in the solar cell 28 shown in FIGS. 32 to 35 are substantially the same as those shown in FIGS. 1 to 3, a further description may be briefly made or may be entirely omitted.

Unlike the solar cell 11 shown in FIGS. 1 and 2, in the solar cell 28 shown in FIGS. 32 to 35, a plurality of first electrodes 141 connected to the emitter region 121 and the heavily doped region 123 as well as a plurality of second electrodes 151 connected to a plurality of BSF regions 172 are formed on the back surface of the substrate 110.

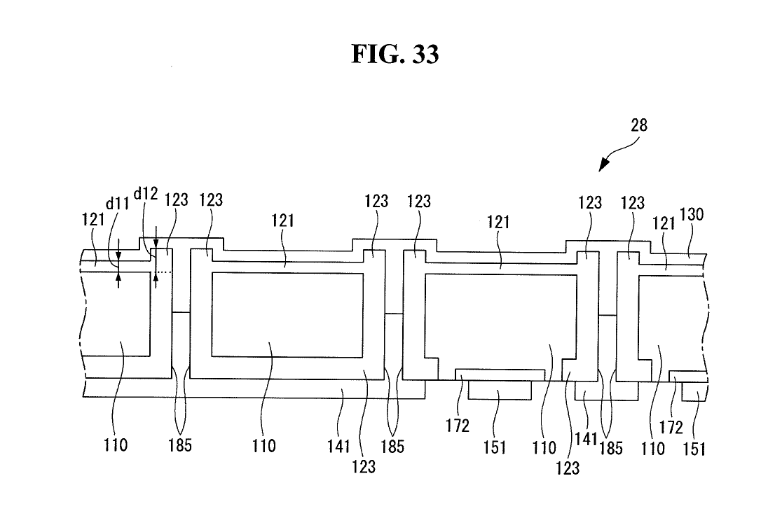

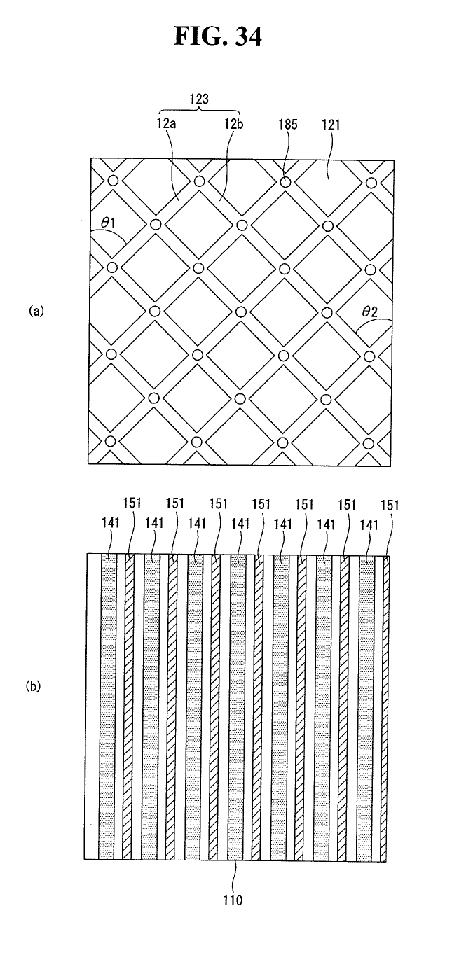

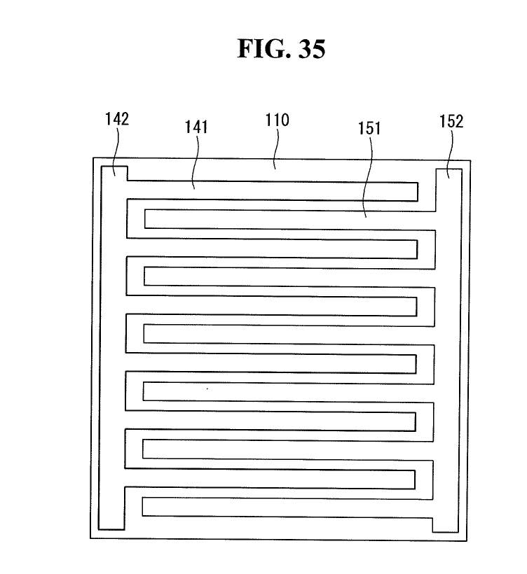

As shown in FIG. 33 and (b) of FIG. 34, the plurality of first electrodes 141 on the back surface of the substrate 110 extend parallel to one another along via holes 185 (i.e., the crossings of the first and second portions 12a and 12b of the heavily doped region 123) of the substrate 110. Further, the plurality of second electrodes 151 on the back surface of the substrate 110 are separated from the first electrodes 141 and extend parallel to one another in the same direction as the extension direction of the first electrodes 141. Thus, the first electrodes 141 and the second electrodes 151 each have a stripe shape. As shown in (b) of FIG. 34 and FIG. 35, the first electrodes 141 and the second electrodes 151 extending in the same direction are alternately positioned on the back surface of the substrate 110.

Because the second electrodes 151 are positioned on the back surface of the substrate 110, the movement of carriers between the substrate 110 and the second electrodes 151 is more easily performed. Further, the BSF regions 172 for preventing a loss of carriers are positioned at the portion of the substrate 110 on which the second electrodes 151 are positioned. Thus, the BSF regions 172 elongate along the second electrodes 151 at the portion of the substrate 110 underlying the second electrodes 151. Hence, the BSF regions 172 each have a stripe shape in the same meaner as the second electrodes 151.

As shown in FIG. 35, a first bus bar 142 connected to the first electrodes 141 and a second bus bar 152 connected to the second electrodes 151 extend at an edge of the back surface of the substrate 110 in a direction vertical to the extension direction (for example, the third and fourth directions) of the first and second electrodes 141 and 151. Thus, each of the first bus bar 142 and the second bus bar 152 is parallel to one side of the substrate 110.

The first bus bar 142 and the second bus bar 152 are positioned opposite each other at the edge of the back surface of the substrate 110 with the first and second electrodes 141 and 151 interposed therebetween.

In the embodiment of the invention, the first electrodes 141 and the first bus bar 142 are formed of the same material, and the second electrodes 151 and the second bus bar 152 are formed of the same material. Further, the first electrodes 141 and the first bus bar 142 are formed of the same material as the second electrodes 151 and the second bus bar 152. Alternatively, the first electrodes 141 and the first bus bar 142 may be formed of a material different from the second electrodes 151 and the second bus bar 152.

Accordingly, the first and second bus bars 142 and 152 may be simultaneously formed when the first and second electrodes 141 and 151 are formed. Further, the first electrodes 141 and the first bus bar 142 may be simultaneously formed in one body, and the second electrodes 151 and the second bus bar 152 may be simultaneously formed in one body.

Because the first and second bus bars 142 and 152 have to collect carriers collected by the first and second electrodes 141 and 151 crossing the first and second bus bars 142 and 152 and have to transfer the carriers in a desired direction, a width of the first and second bus bars 142 and 152 is greater than a width of the first and second electrodes 141 and 151.

However, in an alternative example, the first and second bus bars 142 and 152 may be omitted. In this instance, carriers (for example, electrons) collected by the first electrodes 141 move along a conductive adhesive part (i.e., a conductive connector), which is attached to a corresponding location in a direction crossing the first electrodes 141 and is connected to the first electrodes 141, and an interconnector connected to the conductive adhesive part and then are output to the external device. Further, carriers (for example, holes) collected by the second electrodes 151 move along a conductive adhesive part (i.e., a conductive connector), which is attached to a corresponding location in a direction crossing the second electrodes 151 and is connected to the second electrodes 151, and an interconnector connected to the conductive adhesive part and then are output to the external device. The conductive adhesive parts may be formed of a material different from the first and second electrodes 141 and 151.

Because both the first and second electrodes 141 and 151 are formed on the back surface of the substrate 110, the emitter region 121, the heavily doped region 123, and positioned on the emitter region 121 and the heavily doped region 123 are positioned on the front surface of the substrate 110.

In the solar cell 28, the substrate 110 has a plurality of via holes 185 passing through the substrate 110, so as to electrically and physically connect the emitter region 121 and the heavily doped region 123 positioned at the front surface of the substrate 110 to the first electrodes 141 positioned on the back surface of the substrate 110.

Accordingly, as shown in (a) of FIG. 34, the heavily doped region 123 positioned at the front surface of the substrate 110 includes a first portion 12a extending in the first direction, a second portion 12b extending in the second direction. When the heavily doped region 123, in which the first and second portions 12a and 12b are connected to each other at a crossing of the first and second portions 12a and 12b, is positioned at the front surface of the substrate 110, the plurality of via holes 185 are positioned at the crossing of the first and second portions 12a and 12b.

As shown in FIG. 33, the heavily doped region 123 is positioned even at inner surfaces of the via holes 185, i.e., the sides of the via holes 185.

The heavily doped region 123 is positioned around the formation area of the via holes 185 in the back surface of the substrate 110 and is positioned at the back surface of the substrate 110 in which the via holes 185 are not formed and which adjoins the first electrodes 141. Therefore, the first electrodes 141 are connected to the heavily doped region 123 positioned at the back surface of the substrate 110.

Accordingly, the plurality of first electrodes 141 collect carriers, which are transferred from the front surface of the substrate 110 along the first and second portions 12a and 12b of the heavily doped region 123 adjoining the plurality of via holes 185, and carriers transferred through the heavily doped region 123 positioned at the back surface of the substrate 110. In this instance, because the first electrodes 141 are connected to the heavily doped region 123 having the sheet resistance less than the emitter region 121, a transfer efficiency of carriers is improved.

Because carriers are transferred to the first electrodes 141 along the heavily doped region 123 which has the sheet resistance less than the emitter region 121 and has the conductivity higher than the emitter region 121, an amount of carriers transferred to the first electrodes 141 increases.

In the embodiment of the invention, the anti-reflection layer 130 is positioned on at least a portion of the inner surface of each of the via holes 185, is filled in at least a portion of the inner surface of each via hole 185, and is connected to the first electrodes 141.

As described above, in the embodiment of the invention, the anti-reflection layer 130 is formed of hydrogenated silicon oxide (SiOx), hydrogenated silicon nitride-oxide (SiNxOy), etc. Alternatively, the anti-reflection layer 130 may be formed of a conductive layer capable of transmitting light, for example, transparent conductive oxide (TCO). The anti-reflection layer 130 may be formed may be formed of other materials.

In this instance when the anti-reflection layer 130 is the TCO, for example, at least a portion of carriers moving to the emitter region 121 and the heavily doped region 123 moves to the anti-reflection layer 130 having the sheet resistance less than the emitter region 121 and the heavily doped region 123 and moves inside the via holes 185 along the anti-reflection layer 130. Then, at least a portion of carriers is transferred to the first electrodes 141. Thus, an amount of carriers moving from the anti-reflection layer 130 as well as the heavily doped region 123 to the first electrodes 141 is more than an amount of carriers moving from only the heavily doped region 123 to the first electrodes 141.

The carriers moving to the first electrodes 141 are transferred to the external device through the front bus bar 142. Further, the carriers moving to the second electrodes 151 are transferred to the external device through the second bus bar 152.

As described above, if the first and second bus bars 142 and 152 are omitted, carriers collected by the first and second electrodes 141 and 151 may be transferred to the external device using the conductive adhesive part and/or the interconnector.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a substrate of a first conductive type;
an emitter region of a second conductive type opposite the first conductive type positioned at the substrate, the emitter region having a first sheet resistance;
a first heavily doped region positioned at the substrate, the first heavily doped region having a second sheet resistance less than the first sheet resistance;
a plurality of first electrodes which are positioned on the substrate, overlap at least a portion of the first heavily doped region, and are connected to the at least a portion of the first heavily doped region; and
at least one second electrode which is positioned on the substrate and is connected to the substrate,
wherein the first heavily doped region has at least one of a structure including a first portion extending in a first direction and a second portion extending in a second direction different from the first direction and a structure extending in an oblique direction with respect to a side of the substrate.

2. The solar cell of claim 1, wherein the first portion and the second portion of the first heavily doped region cross each other and form a plurality of crossings,
wherein the first portion and the second portion are connected to each other at the plurality of crossings.

3. The solar cell of claim 2, wherein each of the plurality of first electrodes extends along the plurality of crossings.

4. The solar cell of claim 1, wherein each of the plurality of first electrodes includes a first portion extending in a third direction.

5. The solar cell of claim 4, wherein the third direction is different from the first and second directions.

6. The solar cell of claim 4, wherein the third direction is the same as one of the first and second directions.

7. The solar cell of claim 4, wherein the first heavily doped region is positioned under the plurality of first electrodes and further includes a third portion extending in the third direction along the plurality of first electrodes.

8. The solar cell of claim 4, wherein each of the plurality of first electrodes further includes a second portion extending in a fourth direction different from the third direction.

9. The solar cell of claim 8, wherein the first heavily doped region including the first and second portions is disposed in a first lattice shape at the substrate, and the plurality of first electrodes including the first and second portions are disposed in a second lattice shape on the substrate, and
wherein the first lattice shape and the second lattice shape are staggered at a predetermined angle or are staggered by a predetermined distance in at least one of the third and fourth directions.

10. The solar cell of claim 9, further comprising a first bus bar which is positioned on the substrate and is connected to the plurality of first electrodes.

11. The solar cell of claim 1, further comprising a second heavily doped region having a third sheet resistance less than the second sheet resistance, the second heavily doped region being positioned under the plurality of first electrodes at the substrate and being connected to the plurality of first electrodes.

12. The solar cell of claim 1, wherein the first portion and the second portion of the first heavily doped region do not cross each other and are not connected to each other.

13. The solar cell of claim 1, further comprising a first bus bar which is positioned on the substrate and is connected to the plurality of first electrodes.

14. The solar cell of claim 1, wherein the first heavily doped region further includes a third portion extending in a third direction different from the first and second directions.

15. The solar cell of claim 14, wherein the third portion of the first heavily doped region passes through a crossing of the first and second portions and is connected to the first and second portions.

16. The solar cell of claim 15, wherein each of the plurality of first electrodes includes a main branch, which is positioned on the third portion of the first heavily doped region and extends along the third portion, and at least one subsidiary branch, which is positioned on at least one of the first and second portions of the first heavily doped region and extends along the at least one of the first and second portions, and
wherein the at least one subsidiary branch of one first electrode is separated from another first electrode adjacent to the one first electrode.

17. The solar cell of claim 15, wherein each of the plurality of first electrodes includes a main branch, which extends in a direction crossing the third portion of the first heavily doped region, and at least one subsidiary branch, which is positioned on at least one of the first and second portions of the first heavily doped region and extends along the at least one of the first and second portions.

18. The solar cell of claim 15, wherein each of the plurality of first electrodes includes a main branch, which is positioned on one of the first and second portions of the first heavily doped region and extends along the one portion, and at least one subsidiary branch, which is positioned on the other of the first and second portions of the first heavily doped region and extends along the other portion,
wherein the at least one subsidiary branch of one first electrode is separated from another first electrode adjacent to the one first electrode.

19. The solar cell of claim 14, wherein at least two of the first to third portions of the first heavily doped region do not cross each other and are not connected to each other.

20. The solar cell of claim 13, wherein the substrate has a plurality of via holes passing through the substrate,
wherein the plurality of first electrodes are positioned on a first surface of the substrate, and the first bus bar is positioned on a second surface opposite the first surface of the substrate, and
wherein the plurality of first electrodes, the first bus bar, or both are positioned inside the plurality of via holes, and the plurality of first electrodes and the first bus bar are connected to each other through the plurality of via holes.

21. The solar cell of claim 20, wherein the plurality of via holes are positioned at a location of the substrate corresponding to a crossing of the first and second portions of the first heavily doped region.

22. The solar cell of claim 13, wherein the substrate has a plurality of via holes passing through the substrate,
wherein the plurality of first electrodes and the first bus bar are positioned on a second surface opposite a first surface of the substrate on which light is incident, and
wherein a portion of the first heavily doped region is positioned inside the plurality of via holes and is connected to the plurality of first electrodes.

23. The solar cell of claim 22, wherein the plurality of via holes are positioned at a location of the substrate corresponding to a crossing of the first and second portions of the first heavily doped region.

24. The solar cell of claim 1, wherein the plurality of first electrodes are positioned on a first surface of the substrate,
wherein the at least one second electrode includes a plurality of second electrodes positioned on a second surface opposite the first surface of the substrate, and
wherein the first and second surfaces of the substrate are incident surfaces on which light is incident.
